(19) United States
(12) Patent Application Publication
(10) Pub. No.: US 2024/0147630 A1
(43) Pub. Date: May 2, 2024

(54) ELECTRONIC DEVICE AND MANUFACTURING METHOD OF ELECTRONIC DEVICE

(71) Applicant: FUJIFILM Corporation, Tokyo (JP)

(72) Inventor: Kazuo KAMOHARA, Kanagawa (JP)

(73) Assignee: FUJIFILM Corporation, Tokyo (JP)

(21) Appl. No.: 18/407,463

(22) Filed: Jan. 9, 2024

Related U.S. Application Data
(63) Continuation of application No. PCT/JP2022/027309, filed on Jul. 11, 2022.

(30) Foreign Application Priority Data
Jul. 16, 2021 (JP) 2021-118069

(51) Int. Cl. H05K 3/12; H05K 3/46

(52) U.S. Cl. CPC H05K 3/125; H05K 3/4664; H05K 2203/013

(57) ABSTRACT

There is provided a manufacturing method of an electronic device, the method comprising: a step of preparing an electronic substrate; a step of forming an insulating layer; and a step of forming a conductive layer, in which the step of forming the insulating layer comprises a first step of applying an ink for forming a first insulating layer to a region where the electronic component is not disposed and irradiating the ink for forming a first insulating layer with a first active energy ray and a second step of applying an ink for forming a second insulating layer to a region which includes a region on an insulating layer formed in the first step and a region where the electronic component is disposed, and irradiating the ink for forming a second insulating layer with a second active energy ray.

### CROSS-REFERENCE TO RELATED APPLICATION

This application is a Continuation of International Application No. PCT/JP2022/027309, filed Jul. 11, 2022, which claims priority to Japanese Patent Application No. 2021-118069 filed Jul. 16 2021. Each of the above applications is hereby expressly incorporated by reference, in its entirety, into the present application.

### BACKGROUND OF THE INVENTION

### 1. Field of the Invention

The present disclosure relates to an electronic device and a manufacturing method of an electronic device.

### 2. Description of the Related Art

An electronic component needs to be shielded from interference with electromagnetic waves from other electronic apparatuses, and is generally covered with a shielding can. The shielding can has problems such as being thick, heavy, and having a small degree of freedom in design, and thus, there is a demand for an alternative technique for the shielding can.

For example, JP6654994B discloses a manufacturing method of a circuit component that manufactures a circuit component including an electronic circuit and having an electromagnetic shielding function, the method including: a first molding step of molding an insulating resin on a first surface side of a substrate having a first surface on which an electronic component is mounted and which is provided with a ground electrode, which is a frame-shaped wiring pattern surrounding the electronic component, using a first mold having a plurality of first cavities corresponding to the circuit component; and a second molding step of molding a conductive resin on the first surface side of the substrate, using a second mold having a plurality of second cavities shaped to individually enclose the plurality of first cavities, respectively, in a case of being viewed three-dimensionally, after the first molding step, in which, in the first molding step, molding is performed by bringing a peeling film into contact with an outer peripheral portion of the ground electrode in a clamped state, the electronic component and an inner peripheral portion of the ground electrode are covered with the insulating resin, and the outer peripheral portion of the ground electrode is exposed from the insulating resin as an exposed ground electrode, and in the second molding step, using a compression molding method, the exposed ground electrode and the conductive resin are electrically connected by directly contacting and covering the insulating resin and the exposed ground electrode with the conductive resin.

### SUMMARY OF THE INVENTION

In the manufacturing method disclosed in JP6654994B, a mold having a plurality of cavities is used for manufacturing the insulating resin covering each electronic component, and a degree of freedom in design is small. There is a demand for more easily manufacturing an insulating layer that covers the electronic component.

The present disclosure has been made in view of such circumstances, and according to an embodiment of the present invention, there is provided a manufacturing method of an electronic device using an ink, which has excellent electromagnetic wave-shielding properties.

According to another embodiment of the present invention, there is provided an electronic device having excellent electromagnetic wave-shielding properties, which is obtained using an ink.

The present disclosure includes the following aspects.

<1>

A manufacturing method of an electronic device, the method comprising: a step of preparing an electronic substrate including a wiring board, an electronic component disposed on the wiring board, and a ground electrode; a step of applying an ink for forming an insulating layer to a region on the wiring board where the ground electrode is not included and the electronic component is included and irradiating the ink for forming an insulating layer with an active energy ray to form an insulating layer that is a cured film of the ink for forming an insulating layer; and a step of applying an ink for forming a conductive layer onto the insulating layer and to at least a part of the ground electrode to form a conductive layer that is a cured film of the ink for forming a conductive layer, in which the step of forming the insulating layer includes a first step of applying an ink for forming a first insulating layer to a region where the electronic component is not disposed, and irradiating the ink for forming a first insulating layer with a first active energy ray, and a second step of applying an ink for forming a second insulating layer to a region which includes a region on an insulating layer formed in the first step and a region where the electronic component is disposed, and irradiating the ink for forming a second insulating layer with a second active energy ray.

<2>

The manufacturing method of an electronic device according to <1>, in which the first active energy ray and the second active energy ray are each applied with an illuminance of 4 W/cm² or more.

<3>

The manufacturing method of an electronic device according to <1> or <2>, in which a time from a time point at which the ink for forming a first insulating layer is applied to a start of the irradiation with the first active energy ray is within 1 second, and a time from a time point at which the ink for forming a second insulating layer is applied to a start of the irradiation with the second active energy ray is within 1 second.

<4>

The manufacturing method of an electronic device according to any one of <1> to <3>, in which the ink for forming a first insulating layer and the ink for forming a second insulating layer are each applied by using an ink jet recording method.

<5>

The manufacturing method of an electronic device according to <4>, in which the ink for forming a first insulating layer and the ink for forming a second insulating layer are each applied by using a shuttle scan method.

<6>

The manufacturing method of an electronic device according to any one of <1> to <5>, in which the ink for forming a conductive layer is applied by using an ink jet recording method.

<7>

The manufacturing method of an electronic device according to any one of <1> to <6>, in which the first step includes a step of temporarily curing the ink for forming a first insulating layer and a step of fully curing the temporarily cured ink for forming a first insulating layer, and the second step includes a step of temporarily curing the ink for forming a second insulating layer and a step of fully curing the temporarily cured ink for forming a second insulating layer.

<8>

The manufacturing method of an electronic device according to any one of <1> to <7>, in which the ink for forming a conductive layer contains silver.

<9>

The manufacturing method of an electronic device according to any one of <1> to <8>, in which a content of a surfactant contained in each of the ink for forming a first insulating layer and the ink for forming a second insulating layer is 0.5% by mass or less.

<10>

The manufacturing method of an electronic device according to any one of <1> to <9>, in which the ink for forming a first insulating layer and the ink for forming a second insulating layer are the same, the first step and the second step are each repeated, and a thickness of the insulating layer is in a range of 30 μm to 3000 μm.

<11>

The manufacturing method of an electronic device according to any one of <1> to <10>, in which the ink for forming a first insulating layer and the ink for forming a second insulating layer are the same, the first step and the second step are each repeated, and an absolute value of a difference between a maximum value and a minimum value of a thickness of the insulating layer is 30 μm or more.

<12>

An electronic device comprising: a wiring board; an electronic component disposed on the wiring board; a ground electrode; an insulating layer formed on the wiring board and the electronic component; and a conductive layer formed on the insulating layer and at least a part of the ground electrode, in which a thickness of the insulating layer formed on a region of the wiring board on which the electronic component is not disposed is thicker than a thickness of the insulating layer formed on the electronic component.

<13>

The electronic device according to <12>, in which the thickness of the insulating layer is in a range of 30 μm to 3000 μm.

<14>

The electronic device according to <12> or <13>, in which an absolute value of a difference between a maximum value and a minimum value of the thickness of the insulating layer is 30 μm or more.

According to an embodiment of the present invention, there is provided a manufacturing method of an electronic device using an ink, which has excellent electromagnetic wave-shielding properties.

In addition, according to another embodiment of the present invention, there is provided an electronic device having excellent electromagnetic wave-shielding properties, which is obtained using an ink.

### BRIEF DESCRIPTION OF THE DRAWINGS

FIG. 1 is a schematic plan view of an electronic substrate prepared in a preparation step.

FIG. 2 is a cross-sectional view taken along the line A-A of FIG. 1.

FIG. 3A is a diagram showing an example of an application region of an ink for forming an insulating layer.

FIG. 3B is a diagram showing a state where a part of an insulating layer is formed in the cross-sectional view taken along the line A-A in FIG. 1.

FIG. 4A is a diagram showing an example of an application region of an ink for forming an insulating layer.

FIG. 4B is a diagram showing a state where a part of an insulating layer is formed in the cross-sectional view taken along the line A-A in FIG. 1.

FIG. 5A is a diagram showing an example of an application region of an ink for forming an insulating layer.

FIG. 5B is a diagram showing a state where a part of an insulating layer is formed in the cross-sectional view taken along the line A-A in FIG. 1.

FIG. 6A is a diagram showing an example of an application region of an ink for forming a conductive layer.

FIG. 6B is a diagram showing a state where a conductive layer is formed in the cross-sectional view taken along the line A-A in FIG. 1.

### DESCRIPTION OF THE PREFERRED EMBODIMENTS

Hereinafter, an electronic device and a manufacturing method of an electronic device according to the present disclosure will be described in detail.

In the present specification, a numerical range indicated using “to” means a range including numerical values described before and after “to” as a minimum value and a maximum value, respectively.

In a numerical range described in a stepwise manner in the present specification, an upper limit or a lower limit described in a certain numerical range may be replaced with an upper limit or a lower limit in another numerical range described in a stepwise manner. In addition, in a numerical range described in the present specification, an upper limit or a lower limit described in a certain numerical range may be replaced with a value described in Examples.

In the present specification, in a case in which a plurality of substances corresponding to respective components in a composition are present, the amount of the respective components in the composition means the total amount of the plurality of substances present in the composition unless otherwise specified.

In the present specification, a combination of two or more preferred aspects is a more preferred aspect.

In the present specification, the meaning of the term “step” includes not only an independent step but also a step whose intended purpose is achieved even in a case in which the step is not clearly distinguished from other steps.

In the present specification, the term “image” means general films, and term “image recording” means formation of an image (that is, a film). The concept of “image” in the present specification also includes a solid image.

In the present specification, the term “upper surface” means a side surface on a wiring board on which an electronic component is disposed.

[Manufacturing Method of Electronic Device]

A manufacturing method of an electronic device of the present disclosure includes: a step (hereinafter, referred to as a “preparation step”) of preparing an electronic substrate comprising a wiring board, an electronic component disposed on the wiring board, and a ground electrode; a step (hereinafter, referred to as an “insulating layer forming step”) of applying an ink for forming an insulating layer to a region on the wiring board where the ground electrode is not included and the electronic component is included and irradiating the ink for forming an insulating layer with an active energy ray to form an insulating layer that is a cured film of the ink for forming an insulating layer; and a step (hereinafter, referred to as a “conductive layer forming step”) of applying an ink for forming a conductive layer onto the insulating layer and to at least a part of the ground electrode to form a conductive layer that is a cured film of the ink for forming a conductive layer, in which the step of forming the insulating layer includes a first step of applying an ink for forming a first insulating layer to a region where the electronic component is not disposed, and irradiating the ink for forming a first insulating layer with a first active energy ray, and a second step of applying an ink for forming a second insulating layer to a region which includes a region on an insulating layer formed in the first step and a region where the electronic component is disposed, and irradiating the ink for forming a second insulating layer with a second active energy ray.

In the related art, a shielding can has been used as a member that covers the electronic component to shield the electronic component from interference with electromagnetic waves from other electronic apparatuses. In addition, JP6654994B discloses a method using a mold having a plurality of cavities for covering the electronic component. The present inventor has focused on the fact that the electronic component can be more easily covered than in the related art by using an ink for forming an insulating layer, and has studied a method of forming an insulating layer using the ink for forming an insulating layer.

In the manufacturing method of an electronic device of the present disclosure, the insulating layer forming step includes: a first step of applying an ink for forming a first insulating layer to a region where the electronic component is not disposed and irradiating the ink for forming a first insulating layer with a first active energy ray; and a second step of applying an ink for forming a second insulating layer to a region which includes a region on an insulating layer formed in the first step and a region where the electronic component is disposed, and irradiating the ink for forming a second insulating layer with a second active energy ray. As a result, it is considered that smoothing the uppermost surface of the insulating layer makes it easier for the conductive layer to be uniformly formed by the ink for forming a conductive layer, thus improving the electromagnetic wave-shielding properties.

Hereinafter, an example of the manufacturing method of an electronic device according to an embodiment of the present disclosure will be described with reference to the drawings. Note that the manufacturing method of an electronic device according to the embodiment of the present disclosure is not limited to the following example.

In the following description, substantially the same elements (for example, components or parts) may be designated by the same reference numerals, and redundant description thereof may be omitted.

<Preparation Step>

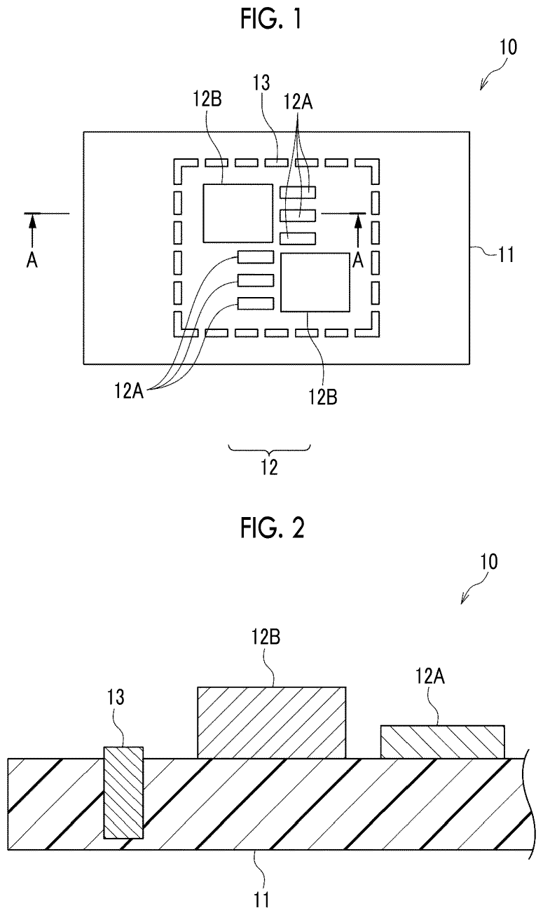

FIG. 1 is a schematic plan view of an electronic substrate prepared in the preparation step. FIG. 2 is a cross-sectional view taken along the line A-A of FIG. 1.

As shown in FIGS. 1 and 2, in the preparation step, an electronic substrate 10 comprising a wiring board 11, electronic components 12 (12A and 12B) disposed on the wiring board 11, and a ground electrode 13 is prepared.

The preparation step may be a step of simply preparing the electronic substrate 10 manufactured in advance, or may be a step of manufacturing the electronic substrate 10.

As a manufacturing method of the electronic substrate 10, a known manufacturing method can be referred to.

Examples of the electronic substrate 10 include a flexible print substrate, a rigid print substrate, and a rigid flexible substrate.

The wiring board refers to one with a wiring on the board and/or inside the board.

Examples of the substrate constituting the wiring board 11 include a glass epoxy substrate, a ceramic substrate, a polyimide substrate, and a polyethylene terephthalate substrate. The substrate may have a monolayer structure or a multilayer structure.

The wiring (not shown) provided on the wiring board 11 is preferably a copper wiring. For example, one end of the wiring is connected to an external power supply, and the other end is connected to a terminal of the electronic component 12.

Examples of the electronic component 12 include a semiconductor chip, a capacitor, and a transistor. The number of the electronic components 12 disposed on the wiring board 11 is not particularly limited. FIG. 1 shows an example in which six electronic components 12A and two electronic components 12B are disposed.

The ground electrode 13 is an electrode to which a ground (GND) potential is applied. In FIG. 1, the ground electrode 13 surrounds the electronic components 12A and 12B and is formed in a discontinuous frame shape in plan view, but a position and a shape of the ground electrode are not limited thereto. For example, the ground electrode may be formed in a continuous frame shape in plan view, or may be formed between the electronic component 12A and the electronic component 12B.

In addition, in FIG. 1, the ground electrode 13 is formed such that a part of the ground electrode 13 in a thickness direction is embedded in the wiring board 10, but the ground electrode in the present disclosure is not limited to this example. For example, the ground electrode may be formed on a surface of the wiring board 11 instead of being embedded in the wiring board 10. In addition, the ground electrode may be formed as a pattern that penetrates the wiring board 11.

<Insulating Layer Forming Step>

In the insulating layer forming step, an ink for forming an insulating layer is applied to a region on the wiring board 11 where the ground electrode 13 is not included and the electronic component 12 is included, and an active energy ray is applied thereto, to form an insulating layer that is a cured film of the ink for forming an insulating layer. Specifically, the insulating layer forming step includes: a first step of applying an ink for forming a first insulating layer to a region where the electronic component 12 is not disposed and irradiating the ink for forming a first insulating layer with a first active energy ray; and a second step of applying an ink for forming a second insulating layer to a region which includes a region on an insulating layer formed in the first step and a region where the electronic component 12 is disposed, and irradiating the ink for forming a second insulating layer with a second active energy ray.

The manufacturing method of an electronic device of the present disclosure includes the above-described first step and the above-described second step, so that smoothing the uppermost surface of the insulating layer that covers the electronic component makes it easier for the conductive layer to be uniformly formed by the ink for forming a conductive layer, thus improving the electromagnetic wave-shielding properties.

Hereinafter, an example of the insulating layer forming step will be described with reference to FIGS. 2, 3A, 3B, 4A, 4B, 5A, and 5B.

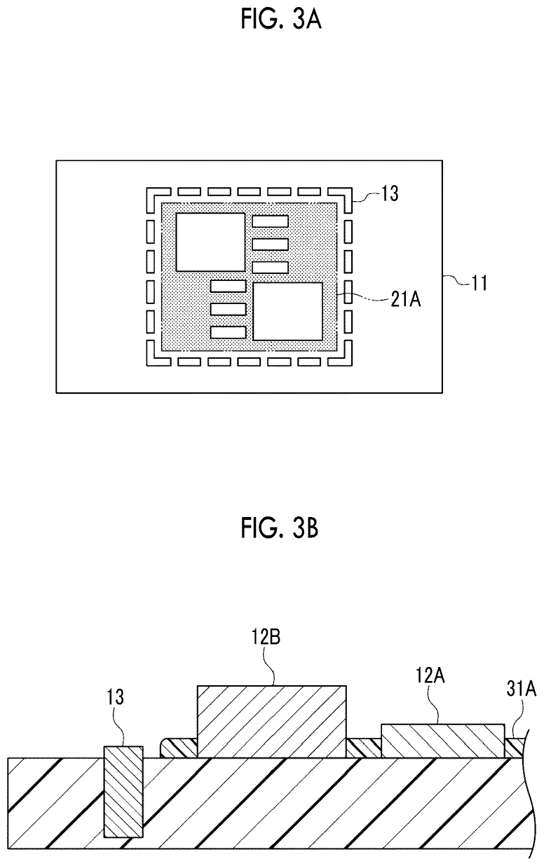

FIG. 2 is a cross-sectional view taken along the line A-A of FIG. 1. FIGS. 3A, 4A, and 5A are diagrams each showing an example of an application region of an ink for forming an insulating layer. FIGS. 3B, 4B, and 5B are diagrams each showing a state where a part of an insulating layer is formed in the cross-sectional view taken along the line A-A in FIG. 1. In this example, as shown in FIG. 2, a height of the electronic component 12B is higher than that of the electronic component 12A.

—First Step—

First, as shown in FIG. 3A, an ink for forming a first insulating layer is applied to a region 21A on the wiring board 11. The region 21A is a region on the wiring board 11 where the ground electrode 13 is not included, the electronic components 12A and 12B are included, and the electronic components 12A and 12B are not disposed.

In this example, the region 21A is located in a region (hereinafter, also referred to as a “ground region”) surrounded by the ground electrode 13, and is narrower than the ground region.

The region 21A can be appropriately set depending on a position and a shape of the electronic component 12 and the ground electrode 13 disposed on the wiring board 11.

Although the first step is a step of applying the ink for forming a first insulating layer to a region where the electronic component is not disposed, a part of the ink for forming a first insulating layer may adhere to a region where the electronic component is disposed, depending on an application accuracy of the ink and the like. Even in a case in which the region 21A is set as a region where the electronic component is not disposed, based on the position and the shape of the electronic component 12 and the ground electrode 13 disposed on the wiring board 11, there may be slight deviation from the region 21A in reality. That is, the concept of “region where the electronic component is not disposed” may include a region where the electronic component is disposed, due to the ink application accuracy or the like.

By performing irradiation with the first active energy ray after the application of the ink for forming a first insulating layer, a film 31A is formed on an outer periphery of the electronic components 12A and 12B as shown in FIG. 3B.

The first step is preferably repeated. By repeating the first step, a thickness of a cured film of the ink for forming a first insulating layer can be increased. For example, the first step is repeated until the thickness of the cured film of the ink for forming a first insulating layer reaches a height of the electronic component 12A having the lowest height among the electronic components 12.

—Second Step a—

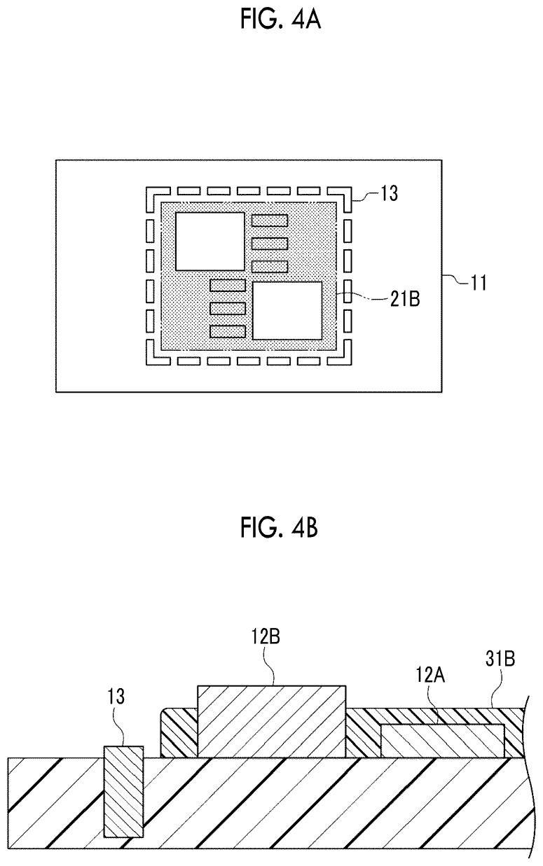

Next, as shown in FIG. 4A, the ink for forming a second insulating layer is applied to a region 21B on the wiring board 11. The region 21B is a region which includes a region on an insulating layer formed in the first step and a region where the electronic component 12A is disposed.

The region 21B is a region obtained by adding a region where the electronic component 12A is disposed, to the region 21A.

By performing irradiation with the second active energy ray after the application of the ink for forming a second insulating layer, a film 31B is formed on an outer periphery of the electronic components 12A and 12B and an upper surface of the electronic component 12A as shown in FIG. 4B.

The second step a is preferably repeated. By repeating the second step a, a thickness of a cured film of the ink for forming a second insulating layer can be increased. For example, the second step a is repeated until the thickness of the cured film of the ink for forming a second insulating layer reaches a height of the electronic component 12B having the second lowest height among the electronic components 12.

—Second Step b—

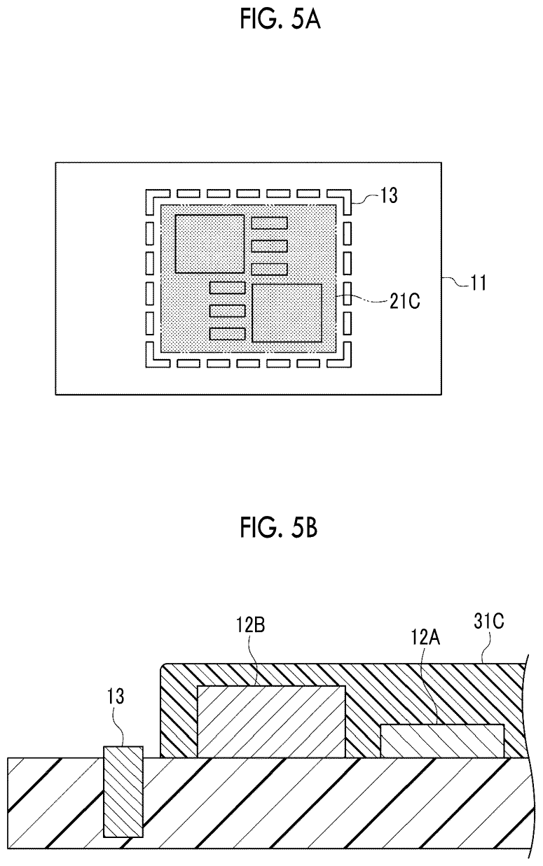

Next, as shown in FIG. 5A, the ink for forming a second insulating layer is applied to a region 21C on the wiring board 11. The region 21C is a region which includes a region on an insulating layer formed in the first step and a region where the electronic components 12A and 12B are disposed. That is, the region 21C is an entire region including the electronic components 12A and 12B on the wiring board 11 where the ground electrode 13 is not disposed.

By performing irradiation with the second active energy ray after the application of the ink for forming a second insulating layer, a film 31C is formed on an outer periphery of the electronic components 12A and 12B and an upper surface of the electronic components 12A and 12B as shown in FIG. 5B.

The second step b is preferably repeated. By repeating the second step b, the thickness of the insulating layer can be increased. The number of times of the second step b is preferably adjusted such that the thickness of the insulating layer is within a range of 30 μm to 3000 μm.

In this example, in a case in which there are two electronic components 12, the region 21A, the region 21B, and the region 21C are set as an application region of the ink for forming an insulating layer, but the present disclosure is not limited to this example.

For example, the position and the shape (planar shape and height) of the ground electrode 13 and the electronic component 12 disposed on the wiring board 11 are read in advance, and the application region of the ink for forming an insulating layer and the number of times of the application of the ink for forming an insulating layer are preferably set based on the read data.

(Insulating Layer)

The insulating layer is a cured film of the ink for forming an insulating layer. Specifically, the insulating layer is formed by performing the first step of applying the ink for forming a first insulating layer and then irradiating the ink for forming a first insulating layer with the first active energy ray, and the second step of applying the ink for forming a second insulating layer and then irradiating the ink for forming a second insulating layer with the second active energy ray.

By repeating each of the first step and the second step, the thickness of the insulating layer can be increased.

In the manufacturing method of an electronic device of the present disclosure, the ink for forming a first insulating layer and the ink for forming a second insulating layer are the same, the first step and the second step are each repeated, and the thickness of the insulating layer is preferably in a range of 30 μm to 3000 μm. That is, it is preferable that the thinnest portion of the insulating layer is 30 μm or more and the thickest portion of the insulating layer is 3000 μm or less.

The phrase “the ink for forming a first insulating layer and the ink for forming a second insulating layer are the same” means that the ink for forming a first insulating layer and the ink for forming a second insulating layer are stored in the same ink tank. Specifically, it means that the ink for forming a first insulating layer and the ink for forming a second insulating layer have the same types and contents of components contained therein.

In a case in which the thickness of the insulating layer is within the above range, the ink for forming a conductive layer is easily formed, thus improving the electromagnetic wave-shielding properties.

In the manufacturing method of an electronic device of the present disclosure, the ink for forming a first insulating layer and the ink for forming a second insulating layer are the same, the first step and the second step are each repeated, and an absolute value of a difference between a maximum value and a minimum value of a thickness of the insulating layer is preferably 30 μm or more, and more preferably 100 μm or more. An upper limit of the absolute value of the difference is not particularly limited and is, for example, 200 μm.

In a case in which the absolute value of the difference between the maximum value and the minimum value of the thickness of the insulating layer is 30 μm or more, the uppermost surface of the insulating layer is easily smoothed. The conductive layer is easily formed uniformly by the ink for forming a conductive layer, thus improving the electromagnetic wave-shielding properties.

In the present disclosure, the thickness of the insulating layer is measured based on the surface of the wiring board.

(Ink for Forming Insulating Layer)

In the present disclosure, the ink for forming an insulating layer means an ink for forming a layer having insulating properties. The insulating properties mean properties of having a volume resistivity of 10¹⁰ Ωcm or more.

Hereinafter, regarding descriptions common to the ink for forming a first insulating layer and the ink for forming a second insulating layer, the inks will be simply described as “ink for forming an insulating layer”.

The ink for forming an insulating layer is preferably an active energy ray curable-type ink.

The ink for forming an insulating layer preferably contains a polymerizable monomer and a polymerization initiator.

—Polymerizable Monomer—

The polymerizable monomer refers to a monomer having at least one polymerizable group in one molecule. The polymerizable group in the polymerizable monomer may be a cationically polymerizable group or a radically polymerizable group. From the viewpoint of curing properties, the polymerizable group is preferably a radically polymerizable group. In addition, from the viewpoint of curing properties, the radically polymerizable group is preferably an ethylenically unsaturated group.

In the present disclosure, the monomer refers to a compound having a molecular weight of 1000 or less. The molecular weight can be calculated from the type and number of atoms constituting the compound.

The polymerizable monomer may be a monofunctional polymerizable monomer having one polymerizable group or a polyfunctional polymerizable monomer having two or more polymerizable groups.

The monofunctional polymerizable monomer is not particularly limited as long as it is a monomer having one polymerizable group. From the viewpoint of curing properties, the monofunctional polymerizable monomer is preferably a monofunctional radically polymerizable monomer, and more preferably a monofunctional ethylenically unsaturated monomer.

Examples of the monofunctional ethylenically unsaturated monomer include monofunctional (meth)acrylate, monofunctional (meth)acrylamide, a monofunctional aromatic vinyl compound, monofunctional vinyl ether, and a monofunctional N-vinyl compound.

Examples of the monofunctional (meth)acrylate include methyl (meth)acrylate, ethyl (meth)acrylate, propyl (meth)acrylate, n-butyl (meth)acrylate, hexyl (meth)acrylate, 2-ethylhexyl (meth)acrylate, tert-octyl (meth)acrylate, isoamyl (meth)acrylate, decyl (meth)acrylate, isodecyl (meth)acrylate, lauryl (meth)acrylate, stearyl (meth)acrylate, isostearyl (meth)acrylate, cyclohexyl (meth)acrylate, 4-n-butyl cyclohexyl (meth)acrylate, 4-tert-butyl cyclohexyl (meth)acrylate, bornyl (meth)acrylate, isobornyl (meth)acrylate, 2-ethylhexyldiglycol (meth)acrylate, butoxyethyl (meth)acrylate, 2-chloroethyl (meth)acrylate, 4-bromobutyl (meth)acrylate, cyanoethyl (meth)acrylate, benzyl (meth)acrylate, butoxymethyl (meth)acrylate, 3-methoxybutyl (meth)acrylate, 2-(2-methoxyethoxy)ethyl (meth)acrylate, 2-(2-butoxyethoxy)ethyl (meth)acrylate, 2,2,2-tetrafluoroethyl (meth)acrylate, 1H,1H,2H,2H-perfluorodecyl (meth)acrylate, 4-butylphenyl (meth)acrylate, phenyl (meth)acrylate, 2,4,5-tetramethylphenyl (meth)acrylate, 4-chlorophenyl (meth)acrylate, 2-phenoxymethyl (meth)acrylate, 2-phenoxyethyl (meth)acrylate, glycidyl (meth)acrylate, glycidyloxybutyl (meth)acrylate, glycidyloxyethyl (meth)acrylate, glycidyloxypropyl (meth)acrylate, tetrahydrofurfuryl (meth)acrylate, 2-hydroxyethyl (meth)acrylate, 3-hydroxypropyl (meth)acrylate, 2-hydroxypropyl (meth)acrylate, 2-hydroxybutyl (meth)acrylate, 3-hydroxybutyl (meth)acrylate, 4-hydroxybutyl (meth)acrylate, cyclic trimethylolpropane formal (meth)acrylate, phenylglycidyl ether (meth)acrylate, dimethylaminoethyl (meth)acrylate, diethylaminoethyl (meth)acrylate, dimethylaminopropyl (meth)acrylate, diethylaminopropyl (meth)acrylate, trimethoxysilylpropyl (meth)acrylate, trimethylsilylpropyl (meth)acrylate, polyethylene oxide monomethyl ether (meth)acrylate, polyethylene oxide (meth)acrylate, polyethylene oxide monoalkyl ether (meth)acrylate, dipropylene glycol (meth)acrylate, polypropylene oxide monoalkyl ether (meth)acrylate, 2-methacryloyloxyethyl succinate, 2-methacryloyloxyhexahydrophthalic acid, 2-methacryloyloxyethyl-2-hydroxypropyl phthalate, ethoxydiethylene glycol (meth)acrylate, butoxydiethylene glycol (meth)acrylate, trifluoroethyl (meth)acrylate, perfluorooctylethyl (meth)acrylate, 2-hydroxy-3-phenoxypropyl (meth)acrylate, ethylene oxide (EO)-modified phenol (meth)acrylate, EO-modified cresol (meth)acrylate, EO-modified nonylphenol (meth)acrylate, propylene oxide (PO)-modified nonylphenol (meth)acrylate, EO-modified-2-ethylhexyl (meth)acrylate, dicyclopentenyl (meth)acrylate, dicyclopentenyloxyethyl (meth)acrylate, dicyclopentanyl (meth)acrylate, (3-ethyl-3-oxetanylmethyl) (meth)acrylate, phenoxyethylene glycol (meth)acrylate, 2-carboxyethyl (meth)acrylate, and 2-(meth)acryloyloxyethyl succinate.

Among these, from the viewpoint of improving heat resistance, the monofunctional (meth)acrylate is preferably a monofunctional (meth)acrylate having an aromatic ring or an aliphatic ring, and is more preferably isobornyl (meth)acrylate, 4-tert-butylcyclohexyl (meth)acrylate, dicyclopentenyl (meth)acrylate, or dicyclopentanyl (meth)acrylate.

Examples of the monofunctional (meth)acrylamide include (meth)acrylamide, N-methyl (meth)acrylamide, N-ethyl (meth)acrylamide, N-propyl (meth)acryl amide, N-n-butyl (meth)acrylamide, N-t-butyl (meth)acrylamide, N-butoxymethyl (meth)acrylamide, N-isopropyl (meth)acrylamide, N-methylol (meth)acrylamide, N,N-dimethyl (meth)acrylamide, N,N-diethyl (meth)acrylamide, and (meth)acryloylmorpholine.

Examples of the monofunctional aromatic vinyl compound include styrene, dimethyl styrene, trimethyl styrene, isopropyl styrene, chloromethyl styrene, methoxy styrene, acetoxystyrene, chlorostyrene, dichlorostyrene, bromostyrene, vinyl benzoic acid methyl ester, 3-methyl styrene, 4-methyl styrene, 3-ethyl styrene, 4-ethyl styrene, 3-propyl styrene, 4-propyl styrene, 3-butyl styrene, 4-butyl styrene, 3-hexyl styrene, 4-hexyl styrene, 3-octyl styrene, 4-octyl styrene, 3-(2-ethylhexyl)styrene, 4-(2-ethylhexyl)styrene, allyl styrene, isopropenyl styrene, butenyl styrene, octenyl styrene, 4-t-butoxycarbonyl styrene, and 4-t-butoxystyrene.

Examples of the monofunctional vinyl ether include methyl vinyl ether, ethyl vinyl ether, propyl vinyl ether, n-butyl vinyl ether, t-butyl vinyl ether, 2-ethylhexyl vinyl ether, n-nonyl vinyl ether, lauryl vinyl ether, cyclohexyl vinyl ether, cyclohexyl methyl vinyl ether, 4-methylcyclohexyl methyl vinyl ether, benzyl vinyl ether, dicyclopentenyl vinyl ether, 2-dicyclopentenoxyethyl vinyl ether, methoxyethyl vinyl ether, ethoxyethyl vinyl ether, butoxyethyl vinyl ether, methoxyethoxyethyl vinyl ether, ethoxyethoxyethyl vinyl ether, methoxypolyethylene glycol vinyl ether, tetrahydrofurfuryl vinyl ether, 2-hydroxyethyl vinyl ether, 2-hydroxypropyl vinyl ether, 4-hydroxybutyl vinyl ether, 4-hydroxymethylcyclohexylmethyl vinyl ether, diethylene glycol monovinyl ether, polyethylene glycol vinyl ether, chloroethyl vinyl ether, chlorobutyl vinyl ether, chloroethoxyethyl vinyl ether, phenylethyl vinyl ether, and phenoxypolyethylene glycol vinyl ether.

Examples of the monofunctional N-vinyl compound include N-vinyl-ε-caprolactam, N-vinyl-2-pyrrolidone, N-vinyloxazolidinone, and N-vinyl-5-methyloxazolidinone.

Among these, from the viewpoint of improving surface curing properties and adhesiveness, the monofunctional N-vinyl compound is preferably a compound having a heterocyclic structure.

The polyfunctional polymerizable monomer is not particularly limited as long as it is a monomer having two or more polymerizable groups. From the viewpoint of curing properties, the polyfunctional polymerizable monomer is preferably a polyfunctional radically polymerizable monomer, and more preferably a polyfunctional ethylenically unsaturated monomer.

Examples of the polyfunctional ethylenically unsaturated monomer include a polyfunctional (meth)acrylate compound and a polyfunctional vinyl ether.

Examples of the polyfunctional (meth)acrylate include ethylene glycol di(meth)acrylate, diethylene glycol di(meth)acrylate, triethylene glycol di(meth)acrylate, polyethylene glycol di(meth)acrylate, propylene glycol di(meth)acrylate, dipropylene glycol di(meth)acrylate, tripropylene glycol di(meth)acrylate, polypropylene glycol di(meth)acrylate, butylene glycol di(meth)acrylate, tetraethylene glycol di(meth)acrylate, neopentyl glycol di(meth)acrylate, 3-methyl-1,5-pentanediol di(meth)acrylate, 1,6-hexanediol di(meth)acrylate, heptanediol di(meth)acrylate, EO-modified neopentyl glycol di(meth)acrylate, PO-modified neopentyl glycol di(meth)acrylate, EO-modified hexanediol di(meth)acrylate, PO-modified hexanediol di(meth)acrylate, octanediol di(meth)acrylate, nonanediol di(meth)acrylate, decanediol di(meth)acrylate, dodecanediol di(meth)acrylate, glycerin di(meth)acrylate, pentaerythritol di(meth)acrylate, ethylene glycol diglycidyl ether di(meth)acrylate, diethylene glycol diglycidyl ether di(meth)acrylate, tricyclodecanedimethanol di(meth)acrylate, tri methylol ethane tri(meth)acrylate, trimethylolpropane tri(meth)acrylate, trimethylolpropane EO-added tri(meth)acrylate, pentaerythritol tri(meth)acrylate, pentaerythritol tetra(meth)acrylate, dipentaerythritol tetra(meth)acrylate, dipentaerythritol penta(meth)acrylate, dipentaerythritol hexa(meth)acrylate, tri(meth)acryloyloxyethoxytrimethylolpropane, glycerin polyglycidyl ether poly(meth)acrylate, and tris(2-acryloyloxyethyl) isocyanurate.

Examples of the polyfunctional vinyl ether include 1,4-butanediol divinyl ether, ethylene glycol divinyl ether, diethylene glycol divinyl ether, triethylene glycol divinyl ether, polyethylene glycol divinyl ether, propylene glycol divinyl ether, butylene glycol divinyl ether, hexanediol divinyl ether, 1,4-cyclohexanedimethanol divinyl ether, bisphenol A alkylene oxide divinyl ether, bisphenol F alkylene oxide divinyl ether, trimethylolethane trivinyl ether, trimethylolpropane trivinyl ether, ditrimethylolpropane tetravinyl ether, glycerin trivinyl ether, pentaerythritol tetravinyl ether, dipentaerythritol pentavinyl ether, dipentaerythritol hexavinyl ether, EO-added trimethylolpropane trivinyl ether, PO-added trimethylolpropane trivinyl ether, EO-added ditrimethylolpropane tetravinyl ether, PO-added ditrimethylolpropane tetravinyl ether, EO-added pentaerythritol tetravinyl ether, PO-added pentaerythritol tetravinyl ether, EO-added dipentaerythritol hexavinyl ether, and PO-added dipentaerythritol hexavinyl ether.

Among these, from the viewpoint of curing properties, the polyfunctional polymerizable monomer is preferably a monomer having 3 to 11 carbon atoms in a portion other than a (meth)acryloyl group. As the monomer having 3 to 11 carbon atoms in a portion other than a (meth)acryloyl group, specifically, 1,6-hexanediol di(meth)acrylate, dipropylene glycol di(meth)acrylate, PO-modified neopentyl glycol di(meth)acrylate, 1,4-butanediol di(meth)acrylate, 3-methyl-1,5-pentanediol di(meth)acrylate, polyethylene glycol di(meth)acrylate (EO chain n=4), or 1,10-decanediol di(meth)acrylate is more preferable.

The content of the polymerizable monomer is preferably 10% by mass to 98% by mass, and more preferably 50% by mass to 98% by mass, with respect to the total amount of the ink for forming an insulating layer.

—Polymerization Initiator—

Examples of the polymerization initiator contained in the ink for forming an insulating layer include an oxime compound, an alkylphenone compound, an acylphosphine compound, an aromatic onium salt compound, an organic peroxide, a thio compound, a hexaarylbisimidazole compound, a borate compound, an azinium compound, a titanocene compound, an active ester compound, a carbon halogen bond-containing compound, and an alkylamine.

Among these, from the viewpoint of further improving conductivity, the polymerization initiator contained in the ink for forming an insulating layer is preferably at least one selected from the group consisting of an oxime compound, an alkylphenone compound, and a titanocene compound, more preferably an alkylphenone compound, and still more preferably at least one selected from the group consisting of an α-aminoalkylphenone compound a benzyl ketal, and an alkylphenone.

The content of the polymerization initiator is preferably 0.5% by mass to 20% by mass, and more preferably 2% by mass to 10% by mass, with respect to the total amount of the ink for forming an insulating layer.

In the present disclosure, the ink for forming an insulating layer may contain other components different from the polymerization initiator and the polymerizable monomer. Examples of the other components include a chain transfer agent, a polymerization inhibitor, a sensitizer, a surfactant, and an additive.

—Chain Transfer Agent—

The ink for forming an insulating layer may contain at least one chain transfer agent.

From the viewpoint of improving reactivity of photopolymerization reaction, the chain transfer agent is preferably a polyfunctional thiol.

Examples of the polyfunctional thiol include aliphatic thiols such as hexane-1,6-dithiol, decane-1,10-dithiol, dimercaptodiethyl ether, and dimercaptodiethyl sulfide, aromatic thiols such as xylylene dimercaptan, 4,4′-dimercaptodiphenylsulfide, and 1,4-benzenedithiol; poly(mercaptoacetate) of a polyhydric alcohol such as ethylene glycol bis(mercaptoacetate), polyethylene glycol bis(mercaptoacetate), propylene glycol bis(mercaptoacetate), glycerin tris(mercaptoacetate), trimethylolethane tris(mercaptoacetate), trimethylolpropane tris(mercaptoacetate), pentaerythritol tetrakis(mercaptoacetate), and dipentaerythritol hexakis(mercaptoacetate); poly(3-mercaptopropionate) of a polyhydric alcohol such as ethylene glycol bis(3-mercaptopropionate), polyethylene glycol bis(3-mercaptopropionate), propylene glycol bis(3-mercaptopropionate), glycerin tris(3-mercaptopropionate), trimethylolethane tris(mercaptopropionate), trimethylolpropane tris(3-mercaptopropionate), pentaerythritol tetrakis(3-mercaptopropionate), and dipentaerythritol hexakis(3-mercaptopropionate); and poly(mercaptobutyrate) such as 1,4-bis(3-mercaptobutyryloxy)butane, 1,3,5-tris(3-mercaptobutyloxyethyl)-1,3,5-triazine-2,4,6(1H,3H,5H)-trione, and pentaerythritol tetrakis(3-mercaptobutyrate).

—Polymerization Inhibitor—

The ink for forming an insulating layer may contain at least one polymerization inhibitor.

Examples of the polymerization inhibitor include p-methoxyphenol, quinones (for example, hydroquinone, benzoquinone, and methoxybenzoquinone), phenothiazine, catechols, alkylphenols (for example, dibutyl hydroxy toluene (BHT)), alkyl bisphenols, zinc dimethyldithiocarbamate, copper dimethyldithiocarbamate, copper dibutyldithiocarbamate, copper salicylate, thiodipropionic acid esters, mercaptobenzimidazole, phosphites, 2,2,6,6-tetramethylpiperidine-1-oxyl (TEMPO), 2,2,6,6-tetramethyl-4-hydroxypiperidine-1-oxyl (TEMPOL), and tris(N-nitroso-N-phenylhydroxylamine)aluminum salt (also known as Cupferron Al).

Among these, as the polymerization inhibitor, at least one selected from p-methoxyphenol, catechols, quinones, alkylphenols, TEMPO, TEMPOL, and tris(N-nitroso-N-phenylhydroxylamine)aluminum salt is preferable, and at least one selected from p-methoxyphenol, hydroquinone, benzoquinone, BHT, TEMPO, TEMPOL, and tris(N-nitroso-N-phenylhydroxylamine)aluminum salt is more preferable.

In a case in which the ink of the present disclosure contains a polymerization inhibitor, the content of the polymerization inhibitor is preferably 0.01% by mass to 2.0% by mass, more preferably 0.02% by mass to 1.0% by mass, and particularly preferably 0.03% by mass to 0.5% by mass, with respect to the total amount of the ink.

—Sensitizer—

The ink for forming an insulating layer may contain at least one sensitizer.

Examples of the sensitizer include a polynuclear aromatic compound (for example, pyrene, perylene, triphenylene, and 2-ethyl-9,10-dimethoxyanthracene), a xanthene-based compound (for example, fluorescein, eosin, erythrosin, rhodamine B, and rose bengal), a cyanine-based compound (for example, thiacarbocyanine and oxacarbocyanine), a merocyanine-based compound (for example, merocyanine and carbomerocyanine), a thiazine-based compound (for example, thionine, methylene blue, and toluidine blue), an acridine-based compound (for example, acridine orange, chloroflavine, and acryflavine), anthraquinones (for example, anthraquinone), a squarylium-based compound (for example, squarylium), a coumarin-based compound (for example, 7-diethylamino-4-methylcoumarin), a thioxanthone-based compound (for example, isopropylthioxanthone), and a thiochromanone-based compound (for example, thiochromanone). Among these, the sensitizer is preferably a thioxanthone-based compound.

In a case in which the ink for forming an insulating layer contains a sensitizer, the content of the sensitizer is not particularly limited, but is preferably 1.0% by mass to 15.0% by mass, and more preferably 1.5% by mass to 5.0% by mass, with respect to the total amount of the ink for forming an insulating layer.

—Surfactant—

The ink for forming an insulating layer may contain at least one surfactant.

Examples of the surfactant include surfactants disclosed in JP1987-173463A (JP-S62-173463A) and JP1987-183457A (JP-S62-183457A). In addition, examples of the surfactant include anionic surfactants such as dialkyl sulfosuccinate, alkyl naphthalene sulfonate, and a fatty acid salt; nonionic surfactants such as polyoxyethylene alkyl ether, polyoxyethylene alkyl allyl ether, acetylene glycol, and a polyoxyethylene-polyoxypropylene block copolymer; and cationic surfactants such as an alkylamine salt and a quaternary ammonium salt. In addition, the surfactant may be a fluorine-based surfactant or a silicone-based surfactant.

In a case in which the ink for forming an insulating layer contains a surfactant, the content of the surfactant is preferably 0.5% by mass or less, and more preferably 0.1% by mass or less, with respect to the total amount of the ink for forming an insulating layer. A lower limit of the content of the surfactant is not particularly limited. The content of the surfactant may be 0% by mass.

In a case in which the content of the surfactant is 0.5% by mass or less, the ink for forming an insulating layer is difficult to spread after being applied. Therefore, an outflow of the ink for forming an insulating layer is suppressed, thus improving the electromagnetic wave-shielding properties.

—Organic Solvent—

The ink for forming an insulating layer may contain at least one organic solvent.

Examples of the organic solvent include (poly)alkylene glycol monoalkyl ethers such as ethylene glycol monoethyl ether, diethylene glycol monoethyl ether, triethylene glycol monomethyl ether, propylene glycol monomethyl ether (PGME), dipropylene glycol monomethyl ether, and tripropylene glycol monomethyl ether; (poly)alkylene glycol dialkyl ethers such as ethylene glycol dibutyl ether, diethylene glycol dimethyl ether, diethylene glycol diethyl ether, dipropylene glycol diethyl ether, and tetraethylene glycol dimethyl ether; (poly)alkylene glycol acetates such as diethylene glycol acetate; (poly)alkylene glycol diacetates such as ethylene glycol diacetate and propylene glycol diacetate; (poly)alkylene glycol monoalkyl ether acetates such as ethylene glycol monobutyl ether acetate and propylene glycol monomethyl ether acetate, ketones such as methyl ethyl ketone and cyclohexanone; lactones such as γ-butyrolactone; esters such as ethyl acetate, propyl acetate, butyl acetate, 3-methoxybutyl acetate (MBA), methyl propionate, and ethyl propionate; cyclic ethers such as tetrahydrofuran and dioxane; and amides such as dimethylformamide and dimethylacetamide.

In a case in which the ink for forming an insulating layer contains an organic solvent, the content of the organic solvent is preferably 70% by mass or less, and more preferably 50% by mass or less, with respect to the total amount of the ink for forming an insulating layer. A lower limit of the content of the organic solvent is not particularly limited. The content of the organic solvent may be 0% by mass.

—Additive—

As necessary, the ink for forming an insulating layer may contain an additive such as a co-sensitizer, an ultraviolet absorber, an antioxidant, an antifading agent, and a basic compound.

—Physical Properties—

From the viewpoint of improving jetting stability in a case in which the ink for forming an insulating layer is applied by using an ink jet recording method, a pH of the ink for forming an insulating layer is preferably 7 to 10, and more preferably 7.5 to 9.5. The pH is measured at 25° C. using a pH meter, such as a pH meter (model number “HM-31”) manufactured by DKK-Toa Corporation.

The viscosity of the ink for forming an insulating layer is preferably 0.5 mPa·s to 60 mPa·s, and more preferably 2 mPa·s to 40 mPa·s. The viscosity is measured at 25° C. using a viscometer, such as a TV-22 type viscometer manufactured by Toki Sangyo Co., Ltd.

The surface tension of the ink for forming an insulating layer is preferably 60 mN/m or less, more preferably 20 mN/m to 50 mN/m, and still more preferably 25 mN/m to 45 mN/m. The surface tension is measured at 25° C. using a surface tension meter, for example, by a plate method using an automatic surface tension meter (trade name, “CBVP-Z”) manufactured by Kyowa Interface Science Co., Ltd.

(Application of Ink for Forming Insulating Layer)

A method of applying the ink for forming an insulating layer is not particularly limited, and examples thereof include a known method such as a coating method and an ink jet recording method. Among these, from the viewpoint of making it possible to reduce a thickness of an insulating layer to be formed by applying once a small amount of droplets by means of jetting, each of the ink for forming a first insulating layer and the ink for forming a second insulating layer is preferably applied by using an ink jet recording method.

The ink jet recording method may be any of an electric charge control method of jetting an ink by using electrostatic attraction force, a drop-on-demand method (pressure pulse method) using a vibration pressure of a piezo element, an acoustic ink jet method of jetting an ink by using a radiation pressure by means of converting electric signals into acoustic beams and irradiating the ink with the acoustic beams, or a thermal ink jet (Bubble Jet (registered trademark)) method of forming air bubbles by heating an ink and using the generated pressure.

As the ink jet recording method, particularly, an ink jet recording method, disclosed in JP1979-59936A (JP-554-59936A), of jetting an ink from a nozzle using an action force caused by a rapid change in volume of the ink after being subjected to an action of thermal energy can be effectively used.

Regarding the ink jet recording method, the method disclosed in paragraphs 0093 to 0105 of JP2003-306623A can also be referred to.

Examples of ink jet heads used in the ink jet recording method include ink jet heads for a shuttle scan method of performing recording while scanning the heads in a width direction of the electronic substrate using short serial heads and a line method using line heads each of which is formed of recording elements arranged for the entire region of one side of the electronic substrate.

In the manufacturing method of an electronic device of the present disclosure, the application region of the ink for forming a first insulating layer is different from the application region of the ink for forming a second insulating layer. From the viewpoint of convenience in a case in which the ink is continuously applied while the application region is changed, it is preferable that the ink for forming a first insulating layer and the ink for forming a second insulating layer are each applied by using a shuttle scan method.

In the shuttle scan method, it is preferable that a transport direction of the electronic substrate 10 and a moving direction of the ink jet head are orthogonal to each other.

The amount of droplets of the insulating ink jetted from the ink jet head is preferably 1 pL (picoliter) to 100 pL, more preferably 3 pL to 80 pL, and still more preferably 3 pL to 20 pL.

(Irradiation with Active Energy Ray)

In the insulating layer forming step, irradiation with the first active energy ray is performed after the application of the ink for forming a first insulating layer, and irradiation with the second active energy ray is performed after the application of the ink for forming a second insulating layer.

Hereinafter, regarding descriptions common to the first active energy ray and the second active energy ray, the rays will be simply described as “active energy ray”.

Examples of the active energy ray include ultraviolet rays, visible rays, and electron beams. Among these, ultraviolet rays (hereinafter, also referred to as “UV”) are preferable.

A peak wavelength of the ultraviolet rays is preferably 200 nm to 405 nm, more preferably 250 nm to 400 nm, and still more preferably 300 nm to 400 nm.

In the manufacturing method of an electronic device of the present disclosure, it is preferable that the first active energy ray and the second active energy ray are each applied with an illuminance of 4 W/cm² or more.

In a case in which the ground electrode is covered by the outflow of the ink after the application of the ink for forming an insulating layer, the electrical conduction between the ground electrode and the conductive layer may be insufficient, and the electromagnetic wave-shielding properties may deteriorate. With respect to this, by applying the active energy ray with an illuminance of 4 W/cm² or more, an occurrence of wrinkles in the insulating layer is suppressed.

From the viewpoint of further suppressing the occurrence of wrinkles in the insulating layer, the illuminance during the irradiation with the first active energy ray and the second active energy ray is more preferably 8 W/cm² or more, and still more preferably 10 W/cm² or more. An upper limit of the illuminance is not particularly limited, but is, for example, 20 W/cm².

An exposure amount during the irradiation with the first active energy ray and the second active energy ray is preferably 100 mJ/cm² to 10000 mJ/cm², and more preferably 500 mJ/cm² to 7500 mJ/cm².

As will be described below, in a case in which both pinning exposure and main exposure are performed, the term “exposure amount” means a total of the exposure amounts of the pinning exposure and the main exposure. In a case in which only the main exposure is performed without the pinning exposure, the term “exposure amount” means the exposure amount of the main exposure. In addition, the above-described “illuminance” means the illuminance of the main exposure.

From the viewpoint of polymerizing only a part of the polymerizable monomers in the ink for forming an insulating layer, the exposure amount of the pinning exposure is preferably 3 mJ/cm² to 100 mJ/cm², and more preferably 5 mJ/cm² to 20 mJ/cm². The illuminance of the pinning exposure is more preferably 0.2 W/cm² or more, and still more preferably 0.4 W/cm² or more.

Note that in a case in which the application of the ink for forming an insulating layer and the irradiation with the active energy ray are defined as one cycle, the exposure amount mentioned herein means the exposure amount of the active energy ray in one cycle.

As a light source for ultraviolet irradiation, a mercury lamp, a gas laser, and a solid-state laser are mainly used, and a mercury lamp, a metal halide lamp, and an ultraviolet fluorescent lamp are widely known. In addition, a light emitting diode (UV-LED) and a laser diode (UV-LD) are compact, long-life, highly efficient, and low-cost, and are expected to be used as the light source for ultraviolet irradiation. Among these, the light source for ultraviolet irradiation is preferably a metal halide lamp, a high-pressure mercury lamp, a medium-pressure mercury lamp, a low-pressure mercury lamp, or UV-LED.

In addition, in the manufacturing method of an electronic device of the present disclosure, it is preferable that a time from a time point at which the ink for forming a first insulating layer is applied to a start of the irradiation with the first active energy ray is within 1 second, and a time from a time point at which the ink for forming a second insulating layer is applied to a start of the irradiation with the second active energy ray is within 1 second.

The phrase “time point at which the ink for forming an insulating layer is applied” means a time point at which the ink for forming an insulating layer comes into contact with a medium such as an electronic substrate or an electronic component.

In a case in which the first step is repeated, it is preferable that the time from the time point at which the ink for forming a first insulating layer is applied to the start of the irradiation with the first active energy ray is within 1 second each time. Similarly, in a case in which the second step is repeated, it is preferable that the time from the time point at which the ink for forming a second insulating layer is applied to the start of the irradiation with the second active energy ray is within 1 second each time.

In a case in which the time is within 1 second, the outflow of the ink for forming an insulating layer is suppressed, thus improving the electromagnetic wave-shielding properties.

From the viewpoint of further suppressing the outflow of the ink for forming an insulating layer, the time is more preferably within 1 second, and still more preferably within 0.1 seconds. A lower limit of the time is not particularly limited, but is, for example, 0.05 seconds.

In addition, in the manufacturing method of an electronic device of the present disclosure, it is preferable that the first step includes a step of temporarily curing the ink for forming a first insulating layer and a step of fully curing the temporarily cured ink for forming a first insulating layer, and the second step includes a step of temporarily curing the ink for forming a second insulating layer and a step of fully curing the temporarily cured ink for forming a second insulating layer.

By combining the temporary curing and the full curing, the outflow of the ink for forming an insulating layer is suppressed, thus improving the electromagnetic wave-shielding properties.

In the present disclosure, polymerizing only a part of the polymerizable monomers in the ink for forming an insulating layer is referred to as “temporary curing”, and irradiation with the active energy ray for temporary curing is referred to as “pinning exposure”.

In the present disclosure, polymerizing substantially all of the polymerizable monomers in the ink for forming an insulating layer is also referred to as “full curing”, and irradiation with the active energy ray for full curing is also referred to as “main exposure”.

A reaction rate of the ink for forming an insulating layer after the pinning exposure (that is, temporary curing) is preferably 10% to 80%.

Here, the reaction rate of the ink for forming an insulating layer means a polymerization rate of the radically polymerizable monomers in an ink film obtained by high-performance liquid chromatography.

A reaction rate of the ink for forming an insulating layer after the main exposure (that is, full curing) is preferably more than 80% and 100% or less, more preferably 85% to 100%, and still more preferably 90% to 100%.

The reaction rate of the ink for forming an insulating layer is obtained by the following method.

An electronic substrate that has been operated up to completion of the irradiation of the ink for forming an insulating layer with the active energy ray is prepared, and a sample piece having a size of 20 mm×50 mm (hereinafter, referred to as a sample piece after irradiation) is cut out from a region of the electronic substrate where an ink film exists. The cut sample piece after irradiation is immersed in 10 mL of tetrahydrofuran (THF) for 24 hours, thereby obtaining an eluate containing the ink for forming an insulating layer. High-performance liquid chromatography is performed on the obtained eluate to obtain the amount of the polymerizable monomers (hereinafter, referred to as “amount X1 of monomers after irradiation”).

Subsequently, the same operation as described above is performed, except that an ink film on the electronic substrate is not irradiated with the active energy ray, and the amount of the polymerizable monomers (hereinafter, referred to as “amount X1 of monomers before irradiation”) is obtained.

Based on the amount X1 of monomers after irradiation and the amount X1 of monomers before irradiation, the reaction rate (%) of the ink for forming an insulating layer is obtained by the following equation.

Reaction rate (%)=((amount X1 of monomers before irradiation−amount X1 of monomers after irradiation)/amount X1 of monomers before irradiation)×100

<Conductive Layer Forming Step>

In the conductive layer forming step, the ink for forming a conductive layer is applied onto the insulating layer and to at least a part of the ground electrode to form a conductive layer that is a cured film of the ink for forming a conductive layer.

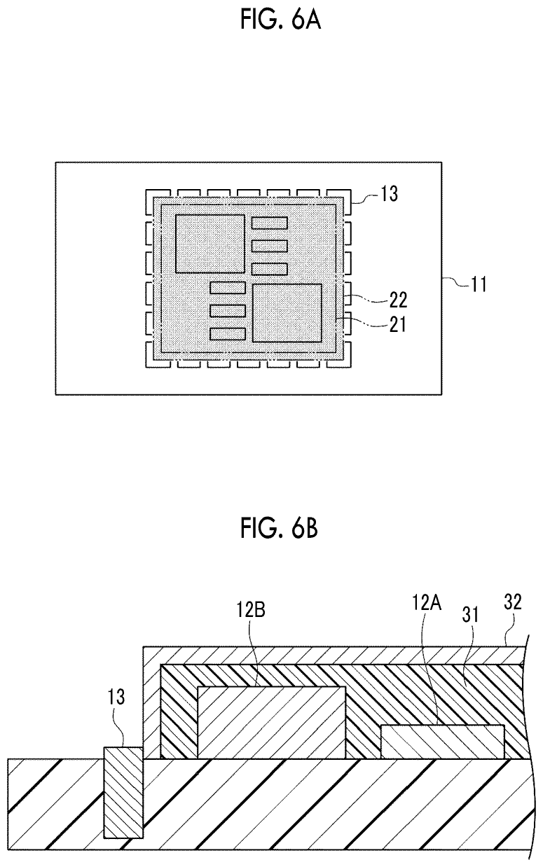

Hereinafter, an example of the conductive layer forming step will be described with reference to FIGS. 6A and 6B.

FIG. 6A is a diagram showing an example of an application region of the ink for forming a conductive layer. FIG. 6B is a diagram showing a state where a conductive layer is formed in the cross-sectional view taken along the line A-A in FIG. 1.

First, as illustrated in FIG. 6A, the ink for forming a conductive layer is applied to a region 22. The region 22 is a region corresponding to a region on an insulating layer 31 and at least a part of the ground electrode 13. In this example, the region 22 is the same region as the ground region.

The region 22 can be appropriately set depending on the position and the shape of the electronic component 12 and the ground electrode 13 disposed on the wiring board 11.

By applying the ink for forming a conductive layer, a conductive layer 32 is formed on the insulating layer 31 and at least a part of the ground electrode 13 as shown in FIG. 6B.

(Conductive Layer)

The conductive layer is a cured film of the ink for forming a conductive layer. Specifically, the conductive layer is formed by applying the ink for forming a conductive layer.

By repeating the conductive layer forming step, a thickness of the conductive layer can be increased.

The thickness of the conductive layer is preferably 0.1 μm to 100 μm, and more preferably 1 μm to 50 μm.

(Ink for Forming Conductive Layer)

In the present disclosure, the ink for forming a conductive layer means an ink for forming a conductive layer having conductivity. The term “conductive” means properties of having a volume resistivity of less than 10⁸ Ωcm.

The ink for forming a conductive layer is preferably an ink containing metal particles (hereinafter, also referred to as a “metal particle ink”), an ink containing a metal complex (hereinafter, also referred to as a “metal complex ink”), or an ink containing a metal salt (hereinafter, also referred to as a “metal salt ink”), and more preferably a metal salt ink or a metal complex ink.

From the viewpoint of improving the electromagnetic wave-shielding properties, the ink for forming a conductive layer is preferably an ink containing silver, and more preferably an ink containing a silver salt or an ink containing a silver complex.

<<Metal Particle Ink>>

The metal particle ink is, for example, an ink composition obtained by dispersing metal particles in a dispersion medium.

—Metal Particles—

Examples of the metal constituting the metal particles include base metal and noble metal particles. Examples of the base metal include nickel, titanium, cobalt, copper, chromium, manganese, iron, zirconium, tin, tungsten, molybdenum, and vanadium. Examples of the noble metal include gold, silver, platinum, palladium, iridium, osmium, ruthenium, rhodium, rhenium, and alloys containing these metals. Among these, from the viewpoint of the conductivity, the metal constituting the metal particles preferably includes at least one selected from the group consisting of silver, gold, platinum, nickel, palladium, and copper, and more preferably includes silver.

An average particle diameter of the metal particles is not particularly limited, but is preferably 10 nm to 500 nm, and more preferably 10 nm to 200 nm. In a case in which the average particle diameter is in the above range, a baking temperature of the metal particles is lowered, which improves process suitability for manufacturing a conductive ink film. In particular, in a case in which the metal particle ink is applied by using a spray method or an ink jet recording method, jettability is improved, which tends to improve pattern forming properties and film thickness uniformity of the conductive ink film. The average particle diameter mentioned herein means an average value of primary particle diameters of the metal particles (average primary particle diameter).

The average particle diameter of the metal particles is measured by a laser diffraction/scattering method. The average particle diameter of the metal particles is, for example, a value obtained by measuring a 50% cumulative volume-based diameter (D50) three times and calculating an average value of D50 measured three times, and can be measured by using a laser diffraction/scattering-type particle size distribution analyzer (trade name “LA-960” manufactured by Horiba, Ltd.).

In addition, the metal particle ink may contain metal particles having an average particle diameter of 500 nm or more, as necessary. In a case in which the metal particle ink contains metal particles having an average particle diameter of 500 nm or more, a melting point of the nm-sized metal particles is lowered around the μm-sized metal particles, which makes it possible to bond the conductive ink film.

The content of the metal particles in the metal particle ink is preferably 10% by mass to 90% by mass, and more preferably 20% by mass to 50% by mass, with respect to the total amount of the metal particle ink. In a case in which the content of the metal particles is 10% by mass or more, a surface resistivity is further reduced. In a case in which the content of the metal particles is 90% by mass or less, jettability is improved in a case in which the metal particle ink is applied by using an ink jet recording method.

In addition to the metal particles, the metal particle ink may contain, for example, a dispersing agent, a resin, a dispersion medium, a thickener, and a surface tension adjuster.

—Dispersing Agent—

The metal particle ink may contain a dispersing agent that adheres to at least a part of a surface of the metal particles. The dispersing agent substantially constitutes metal colloidal particles, together with the metal particles. The dispersing agent has an action of coating the metal particles to improve dispersibility of the metal particles and prevent aggregation. The dispersing agent is preferably an organic compound capable of forming the metal colloidal particles. From the viewpoint of conductivity and dispersion stability, the dispersing agent is preferably an amine, a carboxylic acid, an alcohol, or a resin dispersing agent.

The metal particle ink may contain one dispersing agent or two or more dispersing agents.

Examples of the amine include saturated or unsaturated aliphatic amines. Among these, the amine is preferably an aliphatic amine having 4 to 8 carbon atoms. The aliphatic amine having 4 to 8 carbon atoms may be linear or branched, or may have a ring structure.

Examples of the aliphatic amine include butylamine, normal pentylamine, isopentylamine, hexylamine, 2-ethylhexylamine, and octylamine.

Examples of the amine having an alicyclic structure include cycloalkylamines such as cyclopentylamine and cyclohexylamine.

Examples of an aromatic amine include aniline.

The amine may have a functional group other than an amino group. Examples of the functional group other than an amino group include a hydroxy group, a carboxy group, an alkoxy group, a carbonyl group, an ester group, and a mercapto group.

Examples of the carboxylic acid include formic acid, oxalic acid, acetic acid, hexanoic acid, acrylic acid, octylic acid, oleic acid, tianshic acid, ricinoleic acid, gallic acid, and salicylic acid. A carboxy group, which is a part of the carboxylic acid, may form a salt with a metal ion. The salt may be formed of one metal ion or two or more metal ions.

The carboxylic acid may have a functional group other than the carboxy group. Examples of the functional group other than the carboxy group include an amino group, a hydroxy group, an alkoxy group, a carbonyl group, an ester group, and a mercapto group.

Examples of the alcohol include a terpene-based alcohol, an allyl alcohol, and an oleyl alcohol. The alcohol is likely to be coordinated with the surface of the metal particles, and can suppress the aggregation of the metal particles.

Examples of the resin dispersing agent include a dispersing agent that has a nonionic group as a hydrophilic group and can be uniformly dissolved in a solvent. Examples of the resin dispersing agent include polyvinylpyrrolidone, polyethylene glycol, a polyethylene glycol-polypropylene glycol copolymer, polyvinyl alcohol, polyallylamine, and a polyvinyl alcohol-polyvinyl acetate copolymer. A molecular weight of the resin dispersing agent is preferably 1000 to 50000, and more preferably 1000 to 30000, in terms of a weight-average molecular weight.

The content of the dispersing agent in the metal particle ink is preferably 0.5% by mass to 50% by mass, and more preferably 1% by mass to 30% by mass, with respect to the total amount of the metal particle ink.

—Dispersion Medium—

The metal particle ink preferably contains a dispersion medium. A type of the dispersion medium is not particularly limited, and examples thereof include a hydrocarbon, an alcohol, and water.

The metal particle ink may contain one dispersion medium or two or more dispersion media. The dispersion medium contained in the metal particle ink is preferably volatile. A boiling point of the dispersion medium is preferably 50° C. to 250° C., more preferably 70° C. to 220° C., and still more preferably 80° C. to 200° C. In a case in which the boiling point of the dispersion medium is 50° C. to 250° C., the stability and baking properties of the metal particle ink tend to be simultaneously achieved.

Examples of the hydrocarbon include an aliphatic hydrocarbon and an aromatic hydrocarbon.

Examples of the aliphatic hydrocarbon include a saturated or unsaturated aliphatic hydrocarbon such as tetradecane, octadecane, heptamethylnonane, tetramethylpentadecane, hexane, heptane, octane, nonane, decane, tridecane, methylpentane, normal paraffin, or isoparaffin.

Examples of the aromatic hydrocarbon include toluene and xylene.

Examples of the alcohol include an aliphatic alcohol and an alicyclic alcohol. In a case in which an alcohol is used as the dispersion medium, the dispersing agent is preferably an amine or a carboxylic acid.

Examples of the aliphatic alcohol include a saturated or unsaturated aliphatic alcohol having 6 to 20 carbon atoms that may contain an ether bond in a chain, such as heptanol, octanol (for example, 1-octanol, 2-octanol, or 3-octanol), decanol (for example, 1-decanol), lauryl alcohol, tetradecyl alcohol, cetyl alcohol, 2-ethyl-1-hexanol, octadecyl alcohol, hexadecenol, and oleyl alcohol.

Examples of the alicyclic alcohol include a cycloalkanol such as cyclohexanol; a terpene alcohol such as terpineol (including α, β, and γ isomers, or any mixture of these) or dihydroterpineol; myrtenol, menthol, carveol, perillyl alcohol, pinocarveol, sobrerol, and verbenol.

The dispersion medium may be water. From the viewpoint of adjusting physical properties such as viscosity, surface tension, and volatility, the dispersion medium may be a mixed solvent of water and another solvent. Another solvent to be mixed with water is preferably an alcohol. The alcohol used together with water is preferably an alcohol that is miscible with water and has a boiling point of 130° C. or lower. Examples of the alcohol include 1-propanol, 2-propanol, 1-butanol, 2-butanol, tert-butanol, 1-pentanol, ethylene glycol monomethyl ether, ethylene glycol monoethyl ether, ethylene glycol monopropyl ether, propylene glycol monomethyl ether.

The content of the dispersion medium in the metal particle ink is preferably 1% by mass to 50% by mass, with respect to the total amount of the metal particle ink. In a case in which the content of the dispersion medium is 1% by mass to 50% by mass, the metal particle ink can obtain sufficient conductivity as a conductive ink. The content of the dispersion medium is more preferably 10% by mass to 45% by mass, and still more preferably 20% by mass to 40% by mass.

—Resin—

The metal particle ink may contain a resin. Examples of the resin include polyester, polyurethane, a melamine resin, an acrylic resin, a styrene-based resin, a polyether, and a terpene resin.

The metal particle ink may contain one resin or two or more resins.

The content of the resin in the metal particle ink is preferably 0.1% by mass to 5% by mass with respect to the total amount of the metal particle ink.

—Thickener—

The metal particle ink may contain a thickener. Examples of the thickener include clay minerals such as clay, bentonite, and hectorite; cellulose derivatives such as methyl cellulose, carboxymethyl cellulose, hydroxyethyl cellulose, hydroxypropyl cellulose, and hydroxypropyl methyl cellulose; and polysaccharides such as xanthan gum and guar gum.

The metal particle ink may contain one thickener or two or more thickeners.

The content of the thickener in the metal particle ink is preferably 0.1% by mass to 5% by mass with respect to the total amount of the metal particle ink.

—Surfactant—

The metal particle ink may contain a surfactant. In a case in which the metal particle ink contains a surfactant, a uniform conductive ink film is likely to be formed.

The surfactant may be any of an anionic surfactant, a cationic surfactant, or a nonionic surfactant. Among these, the surfactant is preferably a fluorine-based surfactant from the viewpoint of being able to adjust the surface tension with a small amount of content. In addition, the surfactant is preferably a compound having a boiling point higher than 250° C.

The viscosity of the metal particle ink is not particularly limited. The viscosity of the metal particle ink need only be 0.01 Pa·s to 5000 Pa·s, and is preferably 0.1 Pa·s to 100 Pa·s. In a case in which the metal particle ink is applied by using a spray method or an ink jet recording method, the viscosity of the metal particle ink is preferably 1 mPa·s to 100 mPa·s, more preferably 2 mPa·s to 50 mPa·s, and still more preferably 3 mPa·s to 30 mPa·s.

The viscosity of the metal particle ink is a value measured at 25° C. by using a viscometer. The viscosity is measured using, for example, a VISCOMETER TV-22 type viscometer (manufactured by Toki Sangyo Co., Ltd.).

The surface tension of the metal particle ink is not particularly limited, and is preferably 20 mN/m to 45 mN/m and more preferably 25 mN/m to 40 mN/m.

The surface tension is a value measured at 25° C. by using a surface tension meter.

The surface tension of the metal particle ink is measured using, for example, DY-700 (manufactured by Kyowa Interface Science Co., Ltd.).

—Manufacturing Method of Metal Particles—

The metal particles may be a commercially available product or may be manufactured by a known method. Examples of a manufacturing method of the metal particles include a wet reduction method, a vapor phase method, and a plasma method. Preferred examples of the manufacturing method of the metal particles include a wet reduction method capable of manufacturing metal particles having an average particle diameter of 200 nm or less and having a narrow particle size distribution. Examples of the manufacturing method of the metal particles by a wet reduction method include the method disclosed in JP2017-37761A, WO2014-57633A, and the like, the method including: a step of mixing a metal salt with a reducing agent to obtain a complexing reaction solution; and a step of heating the complexing reaction solution to reduce metal ions in the complexing reaction solution and to obtain a slurry of metal nanoparticles.

In manufacturing the metal particle ink, a heat treatment may be performed such that the content of each component contained in the metal particle ink is adjusted to be in a predetermined range. The heat treatment may be performed under reduced pressure or under normal pressure. In a case in which the heat treatment is performed under normal pressure, the heat treatment may be performed in the atmospheric air or in an inert gas atmosphere.

<<Metal Complex Ink>>

The metal complex ink is, for example, an ink composition obtained by dissolving a metal complex in a solvent.

—Metal Complex—

Examples of metals constituting the metal complex include silver, copper, gold, aluminum, magnesium, tungsten, molybdenum, zinc, nickel, iron, platinum, tin, and lead. Among these, from the viewpoint of conductivity, the metal constituting the metal complex preferably includes at least one selected from the group consisting of silver, gold, platinum, nickel, palladium, and copper, and more preferably includes silver.

The content of the metal contained in the metal complex ink is preferably 1% by mass to 40% by mass, more preferably 5% by mass to 30% by mass, and still more preferably 7% by mass to 20% by mass, with respect to the total amount of the metal complex ink, in terms of the metal element.

The metal complex can be obtained, for example, by reacting a metal salt with a complexing agent. Examples of a manufacturing method of the metal complex include a method of adding a metal salt and a complexing agent to an organic solvent and stirring the mixture for a predetermined time. The stirring method is not particularly limited, and can be appropriately selected from known methods such as a stirring method using a stirrer, a stirring blade, or a mixer, and a method of applying ultrasonic waves.

Examples of the metal salt include a metal oxide, thiocyanate, sulfide, chloride, cyanide, cyanate, carbonate, acetate, nitrate, nitrite, sulfate, phosphate, perchlorate, tetrafluoroborate, an acetyl acetonate complex salt, and carboxylate.

Examples of the complexing agent include an amine, an ammonium carbamate-based compound, an ammonium carbonate-based compound, an ammonium bicarbonate compound, and a carboxylic acid. Among these, from the viewpoint of conductivity and stability of the metal complex, the complexing agent preferably includes at least one selected from the group consisting of an ammonium carbamate-based compound, an ammonium carbonate-based compound, an amine, and a carboxylic acid having 8 to 20 carbon atoms.

The metal complex has a structure derived from a complexing agent, and preferably has a structure derived from at least one selected from the group consisting of an ammonium carbamate-based compound, an ammonium carbonate-based compound, an amine, and a carboxylic acid having 8 to 20 carbon atoms.

Examples of the amine as a complexing agent include ammonia, a primary amine, a secondary amine, a tertiary amine, and a polyamine.

Examples of the primary amine having a linear alkyl group include methylamine, ethylamine, 1-propylamine, n-butylamine, n-pentylamine, n-hexylamine, heptylamine, octylamine, nonylamine, n-decylamine, undecylamine, dodecylamine, tridecylamine, tetradecylamine, pentadecylamine, hexadecylamine, heptadecylamine, and octadecylamine.

Examples of the primary amine having a branched alkyl group include isopropylamine, sec-butylamine, tert-butylamine, isopentylamine, 2-ethylhexylamine, and tert-octylamine.

Examples of the primary amine having an alicyclic structure include cyclohexylamine and dicyclohexylamine.

Examples of the primary amine having a hydroxyalkyl group include ethanolamine, diethanolamine, triethanolamine, N-methylethanolamine, propanolamine, isopropanolamine, dipropanolamine, diisopropanolamine, tripropanolamine, and triisopropanolamine.

Examples of the primary amine having an aromatic ring include benzylamine, N,N-dimethylbenzylamine, phenylamine, diphenylamine, triphenylamine, aniline, N,N-dimethylaniline, N,N-dimethyl-p-toluidine, 4-aminopyridine, and 4-dimethylaminopyridine.

Examples of the secondary amine include dimethylamine, diethylamine, dipropylamine, dibutylamine, diphenylamine, dicyclopentylamine, and methylbutylamine.

Examples of the tertiary amine include trimethylamine, triethylamine, tripropylamine, and triphenylamine.

Examples of the polyamine include ethylenediamine, 1,3-diaminopropane, diethylenetriamine, triethylenetetramine, tetramethylenepentamine, hexamethylenediamine, tetraethylenepentamine, and a combination of these.

The amine is preferably an alkylamine, more preferably an alkylamine having 3 to 10 carbon atoms, and still more preferably a primary alkylamine having 4 to 10 carbon atoms.

The metal complex may be configured of one amine or two or more amines.

In reacting the metal salt with an amine, a ratio of the molar amount of the amine to a molar amount of the metal salt is preferably 1/1 to 15/1, and more preferably 1.5/1 to 6/1. In a case in which the above ratio is within the above range, the complex formation reaction is completed, and a transparent solution is obtained.

Examples of the ammonium carbamate-based compound as a complexing agent include ammonium carbamate, methylammonium methylcarbamate, ethylammonium ethylcarbamate, 1-propylammonium 1-propylcarbamate, isopropylammonium isopropylcarbamate, butylammonium butylcarbamate, isobutylammonium isobutylcarbamate, amylammonium amylcarbamate, hexylammonium hexylcarbamate, heptylammonium heptylcarbamate, octylammonium octylcarbamate, 2-ethylhexylammonium 2-ethylhexylcarbamate, nonylammonium nonylcarbamate, and decylammonium decylcarbamate.

Examples of the ammonium carbonate-based compound as a complexing agent include ammonium carbonate, methylammonium carbonate, ethylammonium carbonate, 1-propylammonium carbonate, isopropylammonium carbonate, butylammonium carbonate, isobutylammonium carbonate, amylammonium carbonate, hexylammonium carbonate, heptylammonium carbonate, octylammonium carbonate, 2-ethylhexylammonium carbonate, nonylammonium carbonate, and decylammonium carbonate.

Examples of the ammonium bicarbonate-based compound as a complexing agent include ammonium bicarbonate, methylammonium bicarbonate, ethylammonium bicarbonate, 1-propylammonium bicarbonate, isopropylammonium bicarbonate, butylammonium bicarbonate, isobutylammonium bicarbonate, amylammonium bicarbonate, hexylammonium bicarbonate, heptylammonium bicarbonate, octylammonium bicarbonate, 2-ethylhexylammonium bicarbonate, nonylammonium bicarbonate, and decylammonium bicarbonate.

In reacting the metal salt with an ammonium carbamate-based compound, an ammonium carbonate-based compound, or an ammonium bicarbonate-based compound, a ratio of a molar amount of the ammonium carbamate-based compound, the ammonium carbonate-based compound, or the ammonium bicarbonate-based compound to the molar amount of the metal salt is preferably 0.01/1 to 1/1, and more preferably 0.05/1 to 0.6/1.

Examples of the carboxylic acid as a complexing agent include caproic acid, caprylic acid, pelargonic acid, 2-ethylhexanoic acid, capric acid, neodecanoic acid, undecanoic acid, lauric acid, myristic acid, palmitic acid, stearic acid, palmitoleic acid, oleic acid, linoleic acid, and linolenic acid. Among these, the carboxylic acid is preferably a carboxylic acid having 8 to 20 carbon atoms, and more preferably a carboxylic acid having 10 to 16 carbon atoms.

The content of the metal complex in the metal complex ink is preferably 10% by mass to 90% by mass, and more preferably 10% by mass to 40% by mass, with respect to the total amount of the metal complex ink. In a case in which the content of the metal complex is 10% by mass or more, the surface resistivity is further reduced. In a case in which the content of the metal complex is 90% by mass or less, jettability is improved in a case in which the metal particle ink is applied by using an ink jet recording method.

—Solvent—

The metal complex ink preferably contains a solvent. The solvent is not particularly limited as long as it can dissolve the component contained in the metal complex ink, such as the metal complex. From the viewpoint of ease of manufacturing, the boiling point of the solvent is preferably 30° C. to 300° C., more preferably 50° C. to 200° C., and still more preferably 50° C. to 150° C.

The content of the solvent in the metal complex ink is preferably set such that the concentration of metal ions with respect to the metal complex (the amount of the metal present as free ions with respect to 1 g of the metal complex) is 0.01 mmol/g to 3.6 mmol/g, and more preferably set such that the concentration of metal ions is 0.05 mmol/g to 2 mmol/g. In a case in which the concentration of metal ions is within the above range, the metal complex ink has excellent fluidity and can obtain conductivity.

Examples of the solvent include a hydrocarbon, a cyclic hydrocarbon, an aromatic hydrocarbon, a carbamate, an alkene, an amide, an ether, an ester, an alcohol, a thiol, a thioether, phosphine, and water. The metal complex ink may contain only one solvent or two or more solvents.

The hydrocarbon is preferably a linear or branched hydrocarbon having 6 to 20 carbon atoms. Examples of the hydrocarbon include pentane, hexane, heptane, octane, nonane, decane, undecane, dodecane, tridecane, tetradecane, pentadecane, hexadecane, octadecane, nonadecane, and icosane.

The cyclic hydrocarbon is preferably a cyclic hydrocarbon having 6 to 20 carbon atoms. The cyclic hydrocarbons can include, for example, cyclohexane, cycloheptane, cyclooctane, cyclononane, cyclodecane, and decalin.

Examples of the aromatic hydrocarbon include benzene, toluene, xylene, and tetraline.

The ether may be any of a linear ether, a branched ether, or a cyclic ether. Examples of the ether include diethyl ether, dipropyl ether, dibutyl ether, methyl-t-butyl ether, tetrahydrofuran, tetrahydropyrane, dihydropyrane, and 1,4-dioxane.

The alcohol may be any of a primary alcohol, a secondary alcohol, or a tertiary alcohol.

Examples of the alcohol include ethanol, 1-propanol, 2-propanol, 1-methoxy-2-propanol, 1-butanol, 2-butanol, 1-pentanol, 2-pentanol, 3-pentanol, 1-hexanol, 2-hexanol, 3-hexanol, 1-octanol, 2-octanol, 3-octanol, tetrahydrofurfuryl alcohol, cyclopentanol, terpineol, decanol, isodecyl alcohol, lauryl alcohol, isolauryl alcohol, myristyl alcohol, isomyristyl alcohol, cetyl alcohol (cetanol), isocetyl alcohol, stearyl alcohol, isostearyl alcohol, oleyl alcohol, isooleyl alcohol, linoleyl alcohol, isolinoleyl alcohol, palmityl alcohol, isopalmityl alcohol, icosyl alcohol, and isoicosyl alcohol.

Examples of the ketone include acetone, methyl ethyl ketone, methyl isobutyl ketone, and cyclohexanone.

Examples of the ester include methyl acetate, ethyl acetate, isopropyl acetate, butyl acetate, isobutyl acetate, sec-butyl acetate, methoxybutyl acetate, ethylene glycol monomethyl ether acetate, ethylene glycol monoethyl ether acetate, ethylene glycol monobutyl ether acetate, diethylene glycol monomethyl ether acetate, diethylene glycol monoethyl ether acetate, diethylene glycol monobutyl ether acetate, propylene glycol monomethyl ether acetate, propylene glycol monoethyl ether acetate, propylene glycol monobutyl ether acetate, dipropylene glycol monomethyl ether acetate, dipropylene glycol monoethyl ether acetate, dipropylene glycol monobutyl ether acetate, and 3-methoxybutyl acetate.

—Reducing Agent—

The metal complex ink may contain a reducing agent. In a case in which the metal complex ink contains a reducing agent, reduction of the metal complex into a metal is facilitated.

Examples of the reducing agent include a borohydride metal salt, an aluminum hydride salt, an amine, an alcohol, an organic acid, reduced sugar, a sugar alcohol, sodium sulfite, a hydrazine compound, dextrin, hydroquinone, hydroxylamine, ethylene glycol, glutathione, and an oxime compound.

The reducing agent may be the oxime compound disclosed in JP2014-516463A. Examples of the oxime compound include acetone oxime, cyclohexanone oxime, 2-butanone oxime, 2,3-butanedione monoxime, dimethyl glyoxime, methyl acetoacetate monoxime, methyl pyruvate monoxime, benzaldehyde oxime, 1-indanone oxime, 2-adamantanone oxime, 2-methylbenzamide oxime, 3-methylbenzamide oxime, 4-methylbenzamide oxime, 3-aminobenzamide oxime, 4-aminobenzamide oxime, acetophenone oxime, benzamide oxime, and pinacolone oxime.

The metal complex ink may contain one reducing agent or two or more reducing agents.

The content of the reducing agent in the metal complex ink is not particularly limited, but is preferably 0.1% by mass to 20% by mass, more preferably 0.3% by mass to 10% by mass, and still more preferably 1% by mass to 5% by mass, with respect to the total amount of the metal complex ink.

—Resin—

The metal complex ink may contain a resin. In a case in which the metal complex ink contains a resin, adhesiveness of the metal complex ink to the electronic substrate is improved.

Examples of the resin include polyester, polyethylene, polypropylene, polyacetal, polyolefin, polycarbonate, polyamide, a fluororesin, a silicone resin, ethyl cellulose, hydroxyethyl cellulose, rosin, an acrylic resin, polyvinyl chloride, polysulfone, polyvinylpyrrolidone, polyvinyl alcohol, a polyvinyl-based resin, polyacrylonitrile, polysulfide, polyamideimide, polyether, polyarylate, polyether ether ketone, polyurethane, an epoxy resin, a vinyl ester resin, a phenol resin, a melamine resin, and a urea resin.

The metal complex ink may contain one resin or two or more resins.

—Additive—

As long as the effects of the present disclosure are not reduced, the metal complex ink may further contain additives such as an inorganic salt, an organic salt, an inorganic oxide such as silica, a surface conditioner, a wetting agent, a crosslinking agent, an antioxidant, a rust inhibitor, a heat-resistant stabilizer, a surfactant, a plasticizer, a curing agent, a thickener, and a silane coupling agent. The total content of the additives in the metal complex ink is preferably 20% by mass or less with respect to the total amount of the metal complex ink.

The viscosity of the metal complex ink is not particularly limited. The viscosity of the metal complex ink need only be 0.01 Pa·s to 5000 Pa·s, and is preferably 0.1 Pa·s to 100 Pa·s. In a case in which the metal complex ink is applied by using a spray method or an ink jet recording method, the viscosity of the metal complex ink is preferably 1 mPa·s to 100 mPa·s, more preferably 2 mPa·s to 50 mPa·s, and still more preferably 3 mPa·s to 30 mPa·s.

The viscosity of the metal complex ink is a value measured at 25° C. by using a viscometer. The viscosity is measured using, for example, a VISCOMETER TV-22 type viscometer (manufactured by Toki Sangyo Co., Ltd.).

The surface tension of the metal complex ink is not particularly limited, and is preferably 20 mN/m to 45 mN/m and more preferably 25 mN/m to 35 mN/m. The surface tension is a value measured at 25° C. by using a surface tension meter.

The surface tension of the metal complex ink is measured using, for example, DY-700 (manufactured by Kyowa Interface Science Co., Ltd.).

<<Metal Salt Ink>>

The metal salt ink is, for example, an ink composition obtained by dissolving a metal salt in a solvent.

—Metal Salt—

Examples of metals constituting the metal salt include silver, copper, gold, aluminum, magnesium, tungsten, molybdenum, zinc, nickel, iron, platinum, tin, and lead. Among these, from the viewpoint of conductivity, the metal constituting the metal salt preferably includes at least one selected from the group consisting of silver, gold, platinum, nickel, palladium, and copper, and more preferably includes silver.

The content of the metal contained in the metal salt ink is preferably 1% by mass to 40% by mass, more preferably 5% by mass to 30% by mass, and still more preferably 7% by mass to 20% by mass, with respect to the total amount of the metal salt ink, in terms of the metal element.

The content of the metal salt in the metal salt ink is preferably 10% by mass to 90% by mass, and more preferably 10% by mass to 40% by mass, with respect to the total amount of the metal salt ink. In a case in which the content of the metal salt is 10% by mass or more, the surface resistivity is further reduced. In a case in which the content of the metal salt is 90% by mass or less, jettability is improved in a case in which the metal particle ink is applied by using a spray method or an ink jet recording method.

Examples of the metal salt include benzoate, halide, carbonate, citrate, iodate, nitrite, nitrate, acetate, phosphate, sulfate, sulfide, trifluoroacetate, and carboxylate of a metal. Two or more salts may be combined.

From the viewpoint of conductivity and storage stability, the metal salt is preferably a metal carboxylate. The carboxylic acid forming the carboxylate is preferably at least one selected from the group consisting of formic acid and a carboxylic acid having 1 to 30 carbon atoms, and more preferably a carboxylic acid having 8 to 20 carbon atoms, and still more preferably a fatty acid having 8 to 20 carbon atoms. The fatty acid may be linear or branched or may have a substituent.

Examples of the linear fatty acid include acetic acid, propionic acid, butyric acid, valeric acid, pentanoic acid, hexanoic acid, heptanoic acid, behenic acid, oleic acid, octanoic acid, nonanoic acid, decanoic acid, caproic acid, enanthic acid, caprylic acid, pelargonic acid, capric acid, and undecanoic acid.

Examples of the branched fatty acid include isobutyric acid, isovaleric acid, ethylhexanoic acid, neodecanoic acid, pivalic acid, 2-methylpentanoic acid, 3-methylpentanoic acid, 4-methylpentanoic acid, 2,2-dimethylbutanoic acid, 2,3-dimethylbutanoic acid, 3,3-dimethylbutanoic acid, and 2-ethylbutanoic acid.

Examples of the carboxylic acid having a substituent include hexafluoroacetylacetonate, hydroangelate, 3-hydroxybutyric acid, 2-methyl-3-hydroxybutyric acid, 3-methoxybutyric acid, acetonedicarboxylic acid, 3-hydroxyglutaric acid, 2-methyl-3-hydroxyglutaric acid, and 2,2,4,4-hydroxyglutaric acid.

The metal salt may be a commercially available product or may be manufactured by a known method. A silver salt is manufactured, for example, by the following method.

First, a silver compound (for example, silver acetate) functioning as a silver supply source and formic acid or a fatty acid having 1 to 30 carbon atoms in the same quantity as the molar equivalent of the silver compound are added to an organic solvent such as ethanol. The mixture is stirred for a predetermined time by using an ultrasonic stirrer, and the formed precipitate is washed with ethanol and decanted. All of these steps can be performed at a room temperature (25° C.). A mixing ratio of the silver compound and the formic acid or fatty acid having 1 to 30 carbon atoms is preferably 1:2 to 2:1, and more preferably 1:1, in terms of molar ratio.

The metal salt ink may contain a solvent, a reducing agent, a resin, and additives. Preferred aspects of the solvent, the reducing agent, the resin, and the additives are the same as the preferred aspects of the solvent, the reducing agent, the resin, and the additives which may be contained in the metal complex ink.

The viscosity of the metal salt ink is not particularly limited. The viscosity of the metal salt ink need only be 0.01 Pa·s to 5000 Pa·s, and is preferably 0.1 Pa·s to 100 Pa s. In a case in which the metal salt ink is applied by using a spray method or an ink jet recording method, the viscosity of the metal salt ink is preferably 1 mPa·s to 100 mPa·s, more preferably 2 mPa·s to 50 mPa·s, and still more preferably 3 mPa·s to 30 mPa·s.

The viscosity of the metal salt ink is a value measured at 25° C. by using a viscometer. The viscosity is measured using, for example, a VISCOMETER TV-22 type viscometer (manufactured by Toki Sangyo Co., Ltd.).

The surface tension of the metal salt ink is not particularly limited, and is preferably 20 mN/m to 45 mN/m and more preferably 25 mN/m to 35 mN/m. The surface tension is a value measured at 25° C. by using a surface tension meter.

The surface tension of the metal salt ink is measured using, for example, DY-700 (manufactured by Kyowa Interface Science Co., Ltd.).

(Application of Ink for Forming Conductive Layer)

A method of applying the ink for forming a conductive layer is not particularly limited, and examples thereof include a known method such as a coating method and an ink jet recording method. Among these, from the viewpoint of making it possible to reduce a thickness of a conductive layer to be formed by applying once a small amount of droplets by means of jetting, the ink for forming a conductive layer is preferably applied by using an ink jet recording method.

A preferred aspect of the ink jet recording method is the same as the preferred aspect of the ink jet recording method in the application of the ink for forming an insulating layer.

It is preferable to preheat the electronic substrate on which the insulating layer is formed, before applying the ink for forming a conductive layer. A temperature of the electronic substrate in a case of applying the ink for forming a conductive layer is preferably 20° C. to 120° C., and more preferably 40° C. to 100° C.

(Formation of Conductive Layer)

It is preferable that the ink for forming a conductive layer is cured using heat or light after being applied onto the insulating layer.

In a case in which the ink for forming a conductive layer is cured using heat, it is preferable that a baking temperature is 250° C. or lower, and a baking time is 1 minute to 120 minutes. In a case in which the baking temperature and the baking time are in the above ranges, the damage of the electronic substrate is suppressed.

The baking temperature is preferably 80° C. to 250° C., and more preferably 100° C. to 200° C. The baking time is preferably 1 minute to 60 minutes.

The baking method is not particularly limited, and a generally known method can be used.

A time from a time point at which the application of the ink for forming a conductive layer is completed to a time point at which the baking is started is preferably 60 seconds or less. A lower limit of the time is not particularly limited, but is, for example, 20 seconds. In a case in which the time is 60 seconds or less, the conductivity is improved.

The phrase “time point at which the application of the conductive ink is completed” refers to a time point at which all the droplets of the conductive ink have been landed on the insulating layer.

In a case in which the ink for forming a conductive layer is cured using light, examples of the light include ultraviolet rays and infrared rays.

A peak wavelength of the ultraviolet rays is preferably 200 nm to 405 nm, more preferably 250 nm to 400 nm, and still more preferably 300 nm to 400 nm.

An exposure amount during the light irradiation is preferably 100 mJ/cm² to 10000 mJ/cm², and more preferably 500 mJ/cm² to 7500 mJ/cm².

[Electronic Device]

An electronic device of the present disclosure comprises: a wiring board; an electronic component disposed on the wiring board; a ground electrode; an insulating layer formed on the wiring board and the electronic component; and a conductive layer formed on the insulating layer and at least a part of the ground electrode, in which a thickness of the insulating layer formed on a region of the wiring board on which the electronic component is not disposed is thicker than a thickness of the insulating layer formed on the electronic component.

In the electronic device of the present disclosure, the thickness of the insulating layer formed on the region of the wiring board on which the electronic component is not disposed is thicker than the thickness of the insulating layer formed on the electronic component, so that the conductive layer is uniformly formed on the insulating layer, thus improving the electromagnetic wave-shielding properties.

The thickness of the insulating layer is preferably in a range of 30 μm to 3000 μm, and more preferably in a range of 100 μm to 2000 μm.

The absolute value of the difference between the maximum value and the minimum value of the thickness of the insulating layer is preferably 30 μm or more, and more preferably 100 μm or more.

Details of each configuration in the electronic device of the present disclosure are as described in the section of the manufacturing method of an electronic device.

### EXAMPLES

Hereinafter, the present disclosure will be described in more detail based on Examples, but the present disclosure is not limited to the following examples unless the gist thereof is overstepped.

First, an ink for forming an insulating layer and an ink for forming a conductive layer were prepared.

<Preparation of Ink for Forming Insulating Layer>

(Insulating Ink 1)

The following components were mixed together, and the mixture was stirred for 20 minutes at 25° C. under a condition of 5000 rpm by using a mixer (trade name “L4R” manufactured by Silverson), thereby obtaining an insulating ink 1.
Omni. 379: 2-(dimethylamino)-2-(4-methylbenzyl)-1-(4-morpholinophenyl)-butan-1-one (trade name “Omnirad 379” manufactured by IGM Resins B.V, Inc.) . . . 4.0% by mass
ITX: 2-isopropylthioxanthone (trade name “SPEEDCURE ITX” manufactured by Lambson Ltd.) . . . 2.0% by mass
PEA: phenoxyethyl acrylate (manufactured by FUJIFILM Wako Pure Chemical Corporation) . . . 49.0% by mass
NVC: N-vinylcaprolactam (manufactured by FUJIFILM Wako Pure Chemical Corporation) . . . 22.0% by mass
TMPTA: trimethylolpropane triacrylate (manufactured by FUJIFILM Wako Pure Chemical Corporation) . . . 23.0% by mass

(Insulating Ink 2)

An insulating ink 2 was obtained in the same manner as the insulating Ink 1, except that a part of PEA in the insulating Ink 1 was changed to 0.1% by mass of BYK-307 (polyether-modified polydimethylsiloxane manufactured by BYK Chemie) as a surfactant.

(Insulating Ink 3)

An insulating ink 3 was obtained in the same manner as the insulating ink 2, except that the content of the surfactant in the insulating ink 2 was changed to 0.5% by mass.

(Insulating Ink 4)

An insulating ink 4 was obtained in the same manner as the insulating ink 2, except that the content of the surfactant in the insulating ink 2 was changed to 1% by mass.

(Insulating Ink 5)

An insulating ink 5 was obtained in the same manner as the insulating ink 2, except that the surfactant in the insulating ink 2 was changed to TEGO (registered trademark) Wet 500 (oxirane, methyl-, oxirane polymer, mono(3,5,5-trimethylhexyl) ether manufactured by Evonik Co., Ltd.).

<Preparation of Ink for Forming Conductive Layer>

40 g of silver neodecanoate was added to a 200 mL three-neck flask. Next, 30.0 g of trimethylbenzene and 30.0 g of terpineol were added thereto and stirred, thereby obtaining a solution containing a silver salt. This solution was filtered using a membrane filter made of polytetrafluoroethylene (PTFE) having a pore diameter of 0.45 μm, thereby obtaining an ink for forming a conductive layer.

<Preparation of Electronic Substrate>

As an electronic substrate, the electronic substrate shown in FIGS. 1 and 2 was prepared. Hereinafter, dimensions of the electronic substrate are shown.

A width of the ground electrode 13: 900 μm

A height of the ground electrode 13 (a height of a portion protruding onto the wiring board 11): 25 μm

A region surrounded by the ground electrode 13: 20 mm×18 mm

A height of the electronic component 12A: 200 μm

A height of the electronic component 12B: 500 μm

A distance between the electronic component 12B and the ground electrode: 200 μm

### Example 1

—Formation of Insulating Layer—

An ink cartridge (for 10 picoliters) of an ink jet recording device (trade name “DMP-2850” manufactured by Fujifilm Dimatix Inc.) was filled with the ink for forming an insulating layer. As image recording conditions, the amount of droplets was set to 10 picoliters per dot. A cycle of applying the ink for forming an insulating layer using pattern image data of the region 21A shown in FIG. 3A and irradiating the ink for forming an insulating layer with ultraviolet rays was repeated twice (first step). Next, a cycle of applying the ink for forming an insulating layer using pattern image data of the region 21B shown in FIG. 4A and irradiating the ink for forming an insulating layer with ultraviolet rays was repeated three times (second a step). Furthermore, a cycle of applying the ink for forming an insulating layer using pattern image data of the region 21C shown in FIG. 5A and irradiating the ink for forming an insulating layer with ultraviolet rays was repeated twice (second b step). The maximum value of the thickness of the insulating layer based on the surface of the wiring board was 700 and the thickness of the insulating layer on the electronic component 12B was 200 The irradiation with ultraviolet rays was performed by using an ultraviolet irradiation device (trade name “UV SPOT CURE OmniCure S2000” manufactured by Lumen Dynamics Group Inc.) installed next to the ink jet head. The illuminance of the ultraviolet rays was set to 4 W/cm² and the irradiation was performed for 0.1 seconds per irradiation, so that the exposure amount per exposure was 0.4 J/cm². By performing the irradiation with ultraviolet rays three times per cycle, the exposure amount per cycle was 1.2 J/cm². In addition, a time from the time point at which the ink for forming an insulating layer is applied to the start of the irradiation with ultraviolet rays occurred was set to 0.1 seconds.

—Formation of Conductive Layer—

An ink cartridge (for 10 picoliters) of an ink jet recording device (trade name “DMP-2850” manufactured by Fujifilm Dimatix Inc.) was filled with the ink for forming a conductive layer. As image recording conditions, the resolution was set to 1270 dots per inch (dpi), and the amount of droplets was set to 10 picoliters per dot. The electronic substrate on which the insulating layer was formed was preheated to 60° C. A cycle of applying the ink for forming a conductive layer using pattern image data of the region 22 shown in FIG. 6A and performing heating at 160° C. for 60 minutes using an oven was repeated eight times. A conductive layer having metallic gloss and a thickness of 3.2 μm was formed, thereby obtaining an electronic device.

### Examples 2 to 17

An electronic device was manufactured in the same manner as in Example 1, except that, in the formation of the insulating layer, the type of the ink for forming an insulating layer, the illuminance of ultraviolet rays, the number of times of the irradiation with ultraviolet rays per cycle, the time from the time point at which the ink for forming an insulating layer is applied to the start of the irradiation with ultraviolet rays, and the maximum value and the minimum value of the thickness of the insulating layer were changed to those shown in Tables 1 to 3.

### Comparative Example 1

An electronic device was manufactured in the same manner as in Example 12, except that the cycle of applying the ink for forming an insulating layer using the pattern image data of the region 21C shown in FIG. 5A instead of using the pattern image data of the region 21A shown in FIG. 3A and the pattern image data of the region 21B shown in FIG. 4A, and irradiating the ink for forming an insulating layer with ultraviolet rays was repeated seven times (second b step).

The electromagnetic wave-shielding properties and the adhesiveness were evaluated using the manufactured electronic device.

<Electromagnetic Wave-Shielding Properties>

100 pieces of each electronic device were manufactured, and whether or not a short circuit occurred was evaluated. The evaluation standards are as follows.
4: No short circuit occurred at all.
3: One electronic device was short-circuited.
2: Two to four electronic devices were short-circuited.
1: Five or more electronic devices were short-circuited.

<Adhesiveness>

After being manufactured, the electronic device was left at 25° C. for 1 hour. After 1 hour, a tape piece of CELLOTAPE (registered trademark, No. 405, manufactured by NICHIBAN Co., Ltd., width of 12 mm, also simply referred to as a “tape” hereinafter) was attached onto the conductive layer. Next, the tape piece was peeled off from the conductive layer to evaluate the adhesiveness between the insulating layer and the conductive layer.

Specifically, the tape was attached and peeled off by the following method.

The tape was unwound at a constant speed and cut in a length of about 75 mm, thereby obtaining a tape piece.

The obtained tape piece was stacked on the conductive layer on the prepared electronic device, and a central region of the tape piece having a width of 12 mm and a length of 25 mm was attached with a finger and rubbed firmly with a fingertip.

After the tape piece was attached, an end of the tape piece was grasped and peeled off in 0.5 seconds to 1.0 second at an angle as close to 60° as possible.

The presence or absence of an attachment on the peeled tape piece and the presence or absence of peeling of the conductive layer in the electronic device were visually observed. The adhesiveness between the insulating layer and the conductive layer was evaluated according to the following evaluation standard. The evaluation standards are as follows.
4: No attachment was observed on the tape piece, and no peeling of the conductive layer was observed.
3: Although some attachments were observed on the tape piece, peeling of the conductive layer was not observed.
2: Although some attachments were observed on the tape piece and slight peeling of the conductive layer was observed, the attachments and the peeling were within an acceptable range for practical use.
1: An attachment was observed on the tape piece, and peeling of the conductive layer was observed, which are out of an acceptable range for practical use.

The evaluation results are shown in Tables 1 to 3. In Tables 1 to 3, the term “Presence or absence of “first step+second step”” means where or not both the first step of applying the ink for forming an insulating layer to a region where the electronic component is not disposed and irradiating the ink for forming an insulating layer with ultraviolet rays and the second step of applying the ink for forming an insulating layer to a region which includes the region where the electronic component is not disposed and a region where the electronic component is disposed, and irradiating the ink for forming an insulating layer with ultraviolet rays were performed in the insulating layer forming step. The term “Maximum value of thickness of insulating layer” means a value of the thickest portion in the thickness of the formed insulating layer. Specifically, the thickest insulating layer is an insulating layer formed at a position where the electronic component is not disposed. The term “Minimum value of thickness of insulating layer” means a value of the thinnest portion in the thickness of the formed insulating layer. Specifically, the thinnest insulating layer is an insulating layer formed on the electronic component 12B having the highest height.

TABLE 1

| | | Example 1 | Example 2 | Example 3 | Example 4 | Example 5 | Example 6 | Example 7 |
|---|---|---|---|---|---|---|---|---|
| Presence or absence of | | Present | Present | Present | Present | Present | Present | Present |
| “first step + second step” | | | | | | | | |
| UV illuminance per | | 4 | 6 | 9 | 12 | 12 | 12 | 12 |
| irradiation (W/cm²) | | | | | | | | |
| UV exposure amount per | | 0.4 | 0.6 | 0.9 | 1.2 | 1.2 | 1.2 | 1.2 |
| exposure (J/cm²) | | | | | | | | |
| The number of time of UV | | 3 | 3 | 2 | 1 | 1 | 1 | 1 |
| irradiation per cycle | | | | | | | | |
| UV exposure amount per | | 1.2 | 1.8 | 1.8 | 1.2 | 1.2 | 1.2 | 1.2 |
| cycle (J/cm²) | | | | | | | | |
| Type of ink for forming | | Insulating | Insulating | Insulating | Insulating | Insulating | Insulating | Insulating |
| insulating layer | | ink 1 | ink 1 | ink 1 | ink 1 | ink 1 | ink 1 | ink 1 |
| Surfactant | BYK307 | — | — | — | — | — | — | — |
| | TEGO Wet500 | — | — | — | — | — | — | — |
| Time to UV | | 0.1 | 0.1 | 0.1 | 0.1 | 0.5 | 1 | 2 |
| irradiation (seconds) | | | | | | | | |
| Maximum value of | | 700 | 700 | 700 | 700 | 700 | 700 | 700 |
| thickness of | | | | | | | | |
| insulating layer (μm) | | | | | | | | |
| Minimum value of | | 200 | 200 | 200 | 200 | 200 | 200 | 200 |
| thickness of | | | | | | | | |
| insulating layer (μm) | | | | | | | | |
| Evaluation | Electromagnetic | 3 | 3 | 3 | 4 | 3 | 3 | 2 |
| | wave-shielding | | | | | | | |
| | property | | | | | | | |
| | Adhesiveness | 3 | 3 | 4 | 4 | 4 | 4 | 4 |

TABLE 2

| | | Example | Example | Example | Example | Example | Example | Example |
|---|---|---|---|---|---|---|---|---|
| | | 8 | 9 | 10 | 11 | 12 | 13 | 14 |
| Presence or absence of | | Present | Present | Present | Present | Present | Present | Present |
| “first step + second step” | | | | | | | | |
| UV illuminance per | | 12 | 12 | 12 | 12 | 12 | 2 | 2 |
| irradiation (W/cm²) | | | | | | | | |
| UV exposure amount per | | 1.2 | 1.2 | 1.2 | 1.2 | 1.2 | 0.2 | 0.2 |
| exposure (J/cm²) | | | | | | | | |
| The number of time of UV | | 1 | 1 | 1 | 1 | 2 | 3 | 6 |
| irradiation per cycle | | | | | | | | |
| UV exposure amount per cycle | | 1.2 | 1.2 | 1.2 | 1.2 | 2.4 | 0.6 | 1.2 |
| (J/cm²) | | | | | | | | |
| Type of ink for forming | | Insulating | Insulating | Insulating | Insulating | Insulating | Insulating | Insulating |
| insulating layer | | ink 2 | ink 3 | ink 4 | ink 5 | ink 1 | ink 1 | ink 1 |
| Surfactant | BYK307 | 0.1 | 0.5 | 1 | — | — | — | — |
| | TEGO Wet500 | — | — | — | 0.5 | — | — | — |
| Time to UV irradiation (seconds) | | 0.5 | 0.5 | 0.1 | 0.5 | 0.1 | 0.1 | 0.1 |
| Maximum value of thickness of | | 700 | 700 | 700 | 700 | 700 | 700 | 700 |
| insulating layer (μm) | | | | | | | | |
| Minimum value of thickness of | | 200 | 200 | 200 | 200 | 200 | 200 | 200 |
| insulating layer (μm) | | | | | | | | |
| Evaluation | Electromagnetic wave- | 3 | 3 | 2 | 3 | 4 | 2 | 2 |
| | shielding property | | | | | | | |
| | Adhesiveness | 4 | 4 | 4 | 4 | 4 | 2 | 2 |

TABLE 3

| | | Example | Example | Comparative |
|---|---|---|---|---|
| | | 15 | 16 | Example 1 |
| Presence or absence of “first | | Present | Present | Absent |
| step + second step” | | | | |
| UV illuminance per | | 12 | 12 | 12 |
| irradiation (W/cm²) | | | | |
| UV exposure amount per | | 1.2 | 1.2 | 1.2 |
| exposure (J/cm²) | | | | |
| The number of time of UV | | 2 | 2 | 2 |
| irradiation per cycle | | | | |
| UV exposure amount per | | 2.4 | 2.4 | 2.4 |
| cycle (J/cm²) | | | | |
| Type of ink for forming | | Insulating | Insulating | Insulating |
| insulating layer | | ink 1 | ink 1 | ink 1 |
| Surfactant | BYK307 | — | — | — |
| | TEGO Wet500 | — | — | — |
| Time to UV irradiation (seconds) | | 0.1 | 0.1 | 0.1 |
| Maximum value of thickness of | | 500 | 520 | 700 |
| insulating layer (μm) | | | | |
| Minimum value of thickness of | | 0 | 20 | 200 |
| insulating layer (μm) | | | | |
| Evaluation | Electromagnetic wave- | 2 | 2 | 1 |
| | shielding property | | | |
| | Adhesiveness | 2 | 4 | 4 |

As shown in Tables 1 and 2, in Examples 1 to 16, it was found that the insulating layer forming step includes: the first step of applying the ink for forming a first insulating layer to a region where the electronic component is not disposed and irradiating the ink for forming a first insulating layer with the first active energy ray; and the second step of applying the ink for forming a second insulating layer to a region which includes a region on an insulating layer formed in the first step and a region where the electronic component is disposed, and irradiating the ink for forming a second insulating layer with a second active energy ray, so that the electromagnetic wave-shielding properties are excellent.

On the other hand, in Comparative Example 1, it was found that the insulating layer forming step does not include the first step, so that the electromagnetic wave-shielding properties are poor.

In Example 1, the irradiation with an active energy ray was performed with an illuminance of 4 W/cm² or more, so that the electromagnetic wave-shielding properties are excellent compared to Example 14.

In Example 6, the time from the time point at which the ink for forming an insulating layer is applied to the start of the irradiation with the active energy ray is within 1 second, so that the electromagnetic wave-shielding properties are excellent compared to Example 7.

In Example 9, the content of the surfactant in the ink for forming an insulating layer is 0.5% by mass or less, so that the electromagnetic wave-shielding properties are excellent compared to Example 10.

### Example 17

In Example 12, after the application of the ink for forming an insulating layer, the irradiation with ultraviolet rays was performed twice with an illuminance of 12 W/cm². In Example 17, the illuminance of the first irradiation was changed to 300 mW/cm², so that the same results as in Example 12 were obtained.

### Example 18

(Insulating Ink 6)

The following components were mixed together to obtain an insulating ink 6 in the same manner as the insulating ink 1.
Omni. 379: 2-(dimethylamino)-2-(4-methylbenzyl)-1-(4-morpholinophenyl)-butan-1-one (trade name “Omnirad 379” manufactured by IGM Resins B.V, Inc.) . . . 1.0% by mass
4-PBZ: 4-phenylbenzophenone (trade name “Omnirad 4-PBZ” manufactured by IGM Resins B. V.) . . . 7.5% by mass
NVC: N-vinylcaprolactam (manufactured by FUJIFILM Wako Pure Chemical Corporation) . . . 15.0% by mass
HDDA: 1,6-hexanediol diacrylate (trade name “SR238” manufactured by Sartomer Japan Inc.) . . . 25.5% by mass
IBOA: isobornyl acrylate (trade name “SR506” manufactured by Sartomer Japan Inc.) . . . 30.0% by mass
Pentaerythritol tetrakis(3-mercaptobutyrate) trade name “KARENZ MT-PE1” . . . 20.0% by mass
MEHQ: p-methoxyphenol (manufactured by FUJIFILM Wako Pure Chemical Corporation) . . . 1.0% by mass

In Example 18, an electronic device was manufactured in the same manner as in Example 12 except that the insulating ink 6 was used, so that the same results as in Example 12 were obtained.

The entire disclosure of Japanese Patent Application No. 2021-118069, filed Jul. 16, 2021, is incorporated into the present specification by reference. In addition, all documents, patent applications, and technical standards described in the present specification are incorporated in the present specification by reference, to the same extent as in the case where each of the documents, patent applications, and technical standards is specifically and individually described.

What is claimed is:

1. A manufacturing method of an electronic device, the method comprising:
preparing an electronic substrate comprising a wiring board, an electronic component disposed on the wiring board, and a ground electrode;
applying an ink for forming an insulating layer to a region on the wiring board where the ground electrode is not comprised and the electronic component is comprised and irradiating the ink for forming an insulating layer with an active energy ray to form an insulating layer that is a cured film of the ink for forming an insulating layer; and
applying an ink for forming a conductive layer onto the insulating layer and to at least a part of the ground electrode to form a conductive layer that is a cured film of the ink for forming a conductive layer,
wherein the forming the insulating layer comprises
applying an ink for forming a first insulating layer to a region where the electronic component is not disposed, and irradiating the ink for forming a first insulating layer with a first active energy ray, and
applying an ink for forming a second insulating layer to a region which comprises a region on an insulating layer formed in the irradiating with a first active energy ray and a region where the electronic component is disposed, and irradiating the ink for forming a second insulating layer with a second active energy ray.

2. The manufacturing method of an electronic device according to claim 1,
wherein the first active energy ray and the second active energy ray are each applied with an illuminance of 4 W/cm² or more.

3. The manufacturing method of an electronic device according to claim 1,
wherein a time from a time point at which the ink for forming a first insulating layer is applied to a start of the irradiation with the first active energy ray is within 1 second, and
a time from a time point at which the ink for forming a second insulating layer is applied to a start of the irradiation with the second active energy ray is within 1 second.

4. The manufacturing method of an electronic device according to claim 1,
wherein the ink for forming a first insulating layer and the ink for forming a second insulating layer are each applied by using an ink jet recording method.

5. The manufacturing method of an electronic device according to claim 4,
wherein the ink for forming a first insulating layer and the ink for forming a second insulating layer are each applied by using a shuttle scan method.

6. The manufacturing method of an electronic device according to claim 1,
wherein the ink for forming a conductive layer is applied by using an ink jet recording method.

7. The manufacturing method of an electronic device according to claim 1,
wherein the irradiating with a first active energy ray comprises temporarily curing the ink for forming a first insulating layer and fully curing the temporarily cured ink for forming a first insulating layer, and
the irradiating with a second active energy ray comprises temporarily curing the ink for forming a second insulating layer and fully curing the temporarily cured ink for forming a second insulating layer.

8. The manufacturing method of an electronic device according to claim 1,
wherein the ink for forming a conductive layer contains silver.

9. The manufacturing method of an electronic device according to claim 1,
wherein a content of a surfactant contained in each of the ink for forming a first insulating layer and the ink for forming a second insulating layer is 0.5% by mass or less.

10. The manufacturing method of an electronic device according to claim 1,
wherein the ink for forming a first insulating layer and the ink for forming a second insulating layer are the same,
the irradiating with a first active energy ray and the irradiating with a second active energy ray are each repeated, and
a thickness of the insulating layer is in a range of 30 μm to 3000 μm.

11. The manufacturing method of an electronic device according to claim 1,
wherein the ink for forming a first insulating layer and the ink for forming a second insulating layer are the same,
the irradiating with a first active energy ray and the irradiating with a second active energy ray are each repeated, and
an absolute value of a difference between a maximum value and a minimum value of a thickness of the insulating layer is 30 μm or more.
